(19) United States
(12) Patent Application Publication
(10) Pub. No.: US 2026/0123378 A1
(43) Pub. Date: Apr. 30, 2026

(54) MODULAR SEMICONDUCTOR SYSTEM AND METHOD OF MANUFACTURING THEREOF

(71) Applicant: SAMSUNG ELECTRONICS CO., LTD., Suwon-si (KR)

(72) Inventors: Jason MARTINEAU, Fremont, CA (US); Yan LI, Morgan Hill, CA (US)

(73) Assignee: SAMSUNG ELECTRONICS CO., LTD., Suwon-si (KR)

(21) Appl. No.: 19/326,056

(22) Filed: Sep. 11, 2025

Related U.S. Application Data
(60) Provisional application No. 63/713,407, filed on Oct. 29, 2024.

(51) Int. Cl. H01L 23/00; H01L 23/48; H01L 25/16

(52) U.S. Cl. CPC H10W 20/20; H10W 90/00; H10W 72/248

(57) ABSTRACT

Semiconductor systems and methods of manufacturing the semiconductor systems are provided. The semiconductor systems may include a plurality of components, wherein dimensions and/or relationships of the components and their connection regions conform with design rules that enable the components and their interconnectors to be assembled together in various configurations.

### CROSS-REFERENCE TO RELATED APPLICATION

This application is based on and claims the benefit of U.S. Provisional Application No. 63/713,407, filed on Oct. 29, 2024, the disclosure of which is incorporated herein by reference in its entirety.

### BACKGROUND

### 1. Field

Embodiments of the present disclosure relate to a semiconductor system, and a method of manufacturing thereof, and, more particularly, a modular semiconductor system and a method of manufacturing thereof.

### 2. Description of Related Art

A semiconductor system may include a plurality of components (e.g., semiconductor devices) that are connected together. For example, the semiconductor system may be a system-in-package (SIP) that includes a plurality of components (e.g., semiconductor devices, dies, or semiconductor packages) that are packaged together.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

According to some example embodiments of the present disclosure, a semiconductor system may be provided that includes a plurality of components (e.g., semiconductor devices, semiconductor packages, and/or interposers), wherein dimensions and/or relationships of the components and their connection regions conform with design rules (also referred to as modular design rules) that enable the components and their interconnectors to be assembled together in various configurations, thereby maximizing flexibility and cross-compatibility in manufacturing different semiconductor systems. Accordingly, a user may freely customize an arrangement of components within the semiconductor system, and capabilities of the semiconductor system.

According to some example embodiments of the present disclosure, a semiconductor system may include: a plurality of components including: a first component including first connection regions at a first surface of the first component; and a second component including second connection regions at a first surface of the second component wherein at least one of the first connection regions is connected to at least one of the second connection regions, wherein a first width of the first component in a first horizontal direction is substantially a first integer multiple of a first fundamental unit width in the first horizontal direction, and wherein a first width of the second component in the first horizontal direction is substantially a second integer multiple of the first fundamental unit width, the second integer multiple being different from the first integer multiple.

According to some example embodiments of the present disclosure, method of manufacturing a semiconductor system may include: selecting, by a computer system, components that are pre-defined in at least one library; creating, by the computer system, an arrangement of the components that are selected; and manufacturing the semiconductor system to include the components in the arrangement, wherein the components include: a first component including first connection regions at a first surface of the first component; and a second component including second connection regions at a first surface of the second component, wherein, in the arrangement, at least one of the first connection regions is connected to at least one of the second connection regions, wherein a first width of the first component in a first horizontal direction is substantially equal to a first integer multiple of a first fundamental unit width in the first horizontal direction, and wherein a first width of the second component in the first horizontal direction is substantially equal to a second integer multiple of the first fundamental unit width, the second integer multiple being different from the first integer multiple.

According to some example embodiments of the present disclosure, a device configured to electrical connect semiconductor components may include: a body; first connection regions arranged in a first pattern at a first surface of the body, the first connection regions respectively including a plurality of first interconnectors arranged in a second pattern; and second connection regions arranged in the first pattern at a second surface of the body, opposite of the first surface, the second connection regions respectively including a plurality of second interconnectors arranged in the second pattern, wherein the plurality of first interconnectors of one of the first connection regions are connected to the plurality of first interconnectors of at least one other of the first connection regions or the plurality of second interconnectors of at least one of the second connection regions.

### BRIEF DESCRIPTION OF DRAWINGS

Example embodiments of the present disclosure will be more clearly understood from the following detailed description taken in conjunction with the accompanying drawings in which:

FIG. 1A illustrates a schematic perspective view showing a component that has fundamental unit dimensions, according to an example embodiment of the present disclosure;

FIG. 1B illustrates a schematic plan view of the component of FIG. 1A, according to an example embodiment of the present disclosure;

FIG. 2A illustrates a schematic perspective view showing a component of a semiconductor system, according to an example embodiment of the present disclosure;

FIG. 2B illustrates a schematic plan view of the component of FIG. 2A, according to an example embodiment of the present disclosure;

FIG. 3A illustrates a schematic plan view of a component in which at least one connection area is omitted in comparison with the component illustrated in FIGS. 2A-2B, according to an example embodiment of the present disclosure.

FIG. 3B illustrates a schematic plan view of a first surface of a component configured according to a first set of modular design rules, according to an example embodiment of the present disclosure.

FIG. 3C illustrates a schematic plan view of a second surface of the component of FIG. 3B configured according to a second set of modular design rules, according to an example embodiment of the present disclosure.

FIG. 4 illustrates a schematic plan view of a connection region of a component of a semiconductor system for connecting to another component, according to an example embodiment of the present disclosure;

FIG. 5A illustrates a schematic perspective view showing a first example of interconnectors of connection regions of a component, according to an example embodiment of the present disclosure;

FIG. 5B illustrates a schematic perspective view showing a second example of interconnections of connection regions of a component, according to an example embodiment of the present disclosure;

FIG. 6A illustrates a schematic plan view showing first horizontal routing of a component for transmission of electrical signals and/or power, according to an example embodiment of the present disclosure;

FIG. 6B illustrates a schematic plan view showing second horizontal routing of a component for transmission of electrical signals and/or power, according to an example embodiment of the present disclosure;

FIG. 7 illustrates a schematic cross-sectional view showing a semiconductor device including an integrated circuit, according to an example embodiment of the present disclosure;

FIG. 8 illustrates a schematic cross-sectional view showing a semiconductor device including an integrated circuit and adapter dies for adapting the integrated circuit to a standardized size, according to an example embodiment of the present disclosure;

FIG. 9A illustrates a schematic plan view showing an interposer of a semiconductor system, according to an example embodiment of the present disclosure; and

FIG. 9B illustrates a schematic cross-sectional view of the interposer, along a line A-A′ of FIG. 9A, according to an example embodiment of the present disclosure.

FIG. 10A illustrates a schematic side view showing a semiconductor system including a vertical stack of two components, according to an example embodiment of the present disclosure;

FIG. 10B illustrates a schematic side view showing a semiconductor system including a vertical stack of three components, according to an example embodiment of the present disclosure;

FIG. 10C illustrates a schematic side view showing a semiconductor system including a stack of components, including interposers, according to an example embodiment of the present disclosure;

FIG. 10D illustrates a schematic side view showing a semiconductor system including a stack of active semiconductor components, according to an example embodiment of the present disclosure;

FIG. 11 illustrates a schematic perspective view showing a semiconductor system including various components having different functions and sizes, according to an example embodiment of the present disclosure;

FIG. 12 illustrates a diagram describing a method of manufacturing a semiconductor system, according to an example embodiment of the present disclosure.

### DETAILED DESCRIPTION

Embodiments of the present disclosure described herein are example embodiments, and thus, the present disclosure is not limited thereto, and may be realized in various other forms. Each of the embodiments provided in the following description is not excluded from being associated with one or more features of another embodiment also provided herein or not provided herein but consistent with the present disclosure. For example, even if matters described in a specific example embodiment are not described in a different example embodiment, the matters may be understood as being related to or combined with the different example embodiment, unless otherwise mentioned in descriptions thereof. In addition, it should be understood that all descriptions of principles, aspects, examples, and embodiments of the present disclosure are intended to encompass structural and functional equivalents thereof. In addition, these equivalents should be understood as including not only currently well-known equivalents but also equivalents to be developed in the future, that is, all devices that perform the same functions regardless of the structures thereof.

It will be understood that when an element, component, layer, pattern, structure, region, or so on (hereinafter collectively “element”) of a semiconductor device (or semiconductor package) is referred to as being “on,” “connected to,” or “coupled to” another element the semiconductor device, it can be directly on, connected to, or coupled to the other element or an intervening element(s) may be present. In contrast, when an element of a semiconductor device is referred to as being “directly on,” “directly connected to,” or “directly coupled to” another element of the semiconductor device, there are no intervening elements present. Like numerals refer to like elements throughout the present disclosure.

Spatially relative terms, such as “over,” “above,” “on,” “upper,” “below,” “under,” “beneath,” “lower,” “left,” “right,” “lower-left,” “lower-right,” “upper-left,” “upper-right,” “central,” “middle,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures.

For example, if the semiconductor device in the figures is turned over, an element described as “below” or “beneath” another element would then be oriented “above” the other element. Thus, the term “below” can encompass both an orientation of above and below. The semiconductor device may be otherwise oriented (rotated 90 degrees or at other orientations) and the spatially relative descriptors used herein interpreted accordingly. As another example, when elements referred to as a “left” element and a “right” element” may be a “right” element and a “left” element when a device or structure including these elements are differently oriented. Thus, in the descriptions here below, the “left” element and the “right” element may also be referred to as a “first” element or a “second” element, respectively, as long as their structural relationship is clearly understood in the context of the descriptions. Similarly, the terms a “lower” element and an “upper” element may be respectively referred to as a “first” element and a “second” element to distinguish the two elements.

It will be understood that, although the terms “first,” “second,” “third,” “fourth,” “fifth,” “sixth,” etc., may be used herein to describe various elements, these elements should not be limited by these terms. These terms are only used to distinguish one element from another element. Thus, a first element discussed below could be termed a second element without departing from the scope of the present disclosure.

As used herein, expressions such as “at least one of,” when preceding a list of elements, modify the entire list of elements and do not modify the individual elements of the list. For example, the expression, “at least one of a, b and c,” should be understood as including only a, only b, only c, both a and b, both a and c, both b and c, or all of a, b and c.

It is to be understood that the terms “about” or “substantially” as used herein with regard to distances, widths, thicknesses, percentages, ranges, etc., are meant to denote being close or approximate to, but not exactly. For example, the term “about” or “substantially” as used herein implies that a small margin of error may be present, such as 5 % or less than the stated amount. Further, when a term “same” or “equal” is used to compare a dimension of two or more elements, the term may cover a “substantially same” or “substantially equal” dimension. Additionally, “substantially same” or “substantially equal” may include the case where dimensions are the “same” or “equal.”

It will be also understood that, when a method of manufacturing an apparatus or structure is described as including a plurality of steps or operations, a certain step or operation described as being performed later than another step or operation may be performed prior to or at the same time as the other step or operation unless the other step or operation is described as necessarily being performed prior to the step or operation. Further, the method may include additional steps or operations not mentioned in the description.

Many example embodiments are described herein with reference to cross-sectional views that are schematic illustrations of the embodiments (and intermediate structures). As such, variations from the shapes of the illustrations as a result of, for example, manufacturing techniques and/or tolerances are to be expected. Thus, the embodiments should not be construed as limited to the particular shapes of regions illustrated herein, and are to include deviations in shapes that result from, for example, manufacturing. Various regions illustrated in the figures are schematic in nature and their shapes may not be intended to illustrate the actual shape of a region of a device and are not intended to limit the scope of the present disclosure. Further, in the drawings, the sizes and relative sizes of layers and regions may be exaggerated for clarity.

For the sake of brevity, conventional elements, structures, or layers included in a semiconductor package including a connection pad, an adhesive layer, an isolation layer, a barrier metal pattern, a seed layer, etc. may or may not be described in detail herein. For example, descriptions of certain connection pads of a semiconductor chip connected to solder balls or bumps in a semiconductor package may be omitted herein when these structural elements are not related to certain features of the embodiments. Also, descriptions of materials forming well-known structural elements may be omitted herein when those materials are not relevant to certain features of the embodiments. Herein, the term “connection” between two structures or elements may refer to an electrical connection therebetween. For example, a connection between semiconductor chips, semiconductor packages, and/or semiconductor devices may refer to an electrical connection of corresponding two or more elements to each other. The terms “coupled” and “connected” may have the same meaning and may be used interchangeably herein. Further, the term “isolation” between two structures or elements pertains to electrical insulation or separation therebetween. For example, isolation of wiring patterns from each other may mean that the wiring patterns are not electrically connected to each other.

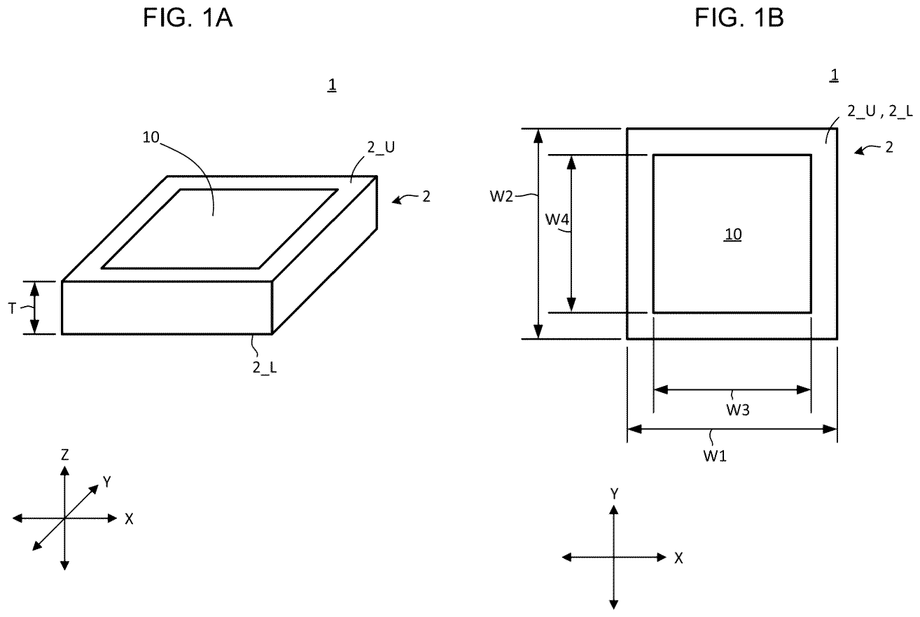

Hereinafter, various non-limiting example embodiments of the present disclosure are described with reference to FIGS. 1A-12.

In comparative embodiments, a plurality of different components (e.g., semiconductor chips) from a variety of vendors may be packaged together into a system-in-package (SIP). In such comparative embodiments, due to the uniqueness of the components, different SIPs may be respectively required to be custom-designed and manufactured. Thus, reusability of resources across projects for producing different SIPs may be limited.

According to some example embodiments of the present disclosure, a semiconductor system (e.g., an SIP) may be provided that includes a plurality of modular components (e.g., semiconductor devices, semiconductor packages, and/or interposers), wherein dimensions and/or relationships of the modular components and their connection regions conform with design rules (also referred to as modular design rules) that enable the modular components and their interconnectors to be assembled together in various configurations, thereby maximizing flexibility and cross-compatibility in manufacturing different semiconductor systems. Accordingly, a user may freely customize an arrangement of components (e.g., modular components) within the semiconductor system, and capabilities of the semiconductor system, and components (e.g., modular components) used to create a first SIP design may be later used in numerous other, alternative SIP designs.

For example, the modular components may have dimensions that are substantially equal to, or an integer multiple of, dimensions of a fundamental unit. Additionally, the plurality of modular components may include connection regions that include a uniform arrangement of the interconnectors, and distances between neighboring ones of the connection regions may substantially be the same as one another, or integer multiples of one another.

With reference to FIGS. 1A-1B, an example of a modular component and the fundamental unit dimensions is described below.

FIG. 1A illustrates a schematic perspective view showing a component 1 (e.g., a modular component) that has the fundamental unit dimensions, according to an example embodiment of the present disclosure. FIG. 1B illustrates a schematic plan view of the component 1 of FIG. 1A, according to an example embodiment of the present disclosure.

According to some embodiments, the component 1 that has the fundamental unit dimensions may be referred to as a fundamental unit, and may include a body 2 and at least one connection region 10.

At least a portion of the body 2 may be configured to perform a function(s) of the component 1. For example, as discussed in detail below, the portion of the body 2 may be configured to perform at least one from among a logic function, a memory function, a sensing function, a connection function, etc. According to embodiments, as discussed in detail below, the body 2 may include one or more layers.

The at least one connection region 10 may be configured to connect the component 1 to another component. For example, as discussed in detail below, connection regions 10 of respective components (e.g., modular components) may be directly or indirectly connected (e.g., electrically connected) together such that the components are connected (e.g., electrically connected) together. The connection region 10 may be provided at (e.g., in or on) a surface of the body 2. For example, the connection region 10 may be provided at (e.g., in or on) an upper surface 2_U of the body 2 or a lower surface 2_L of the body 2. According to embodiments, one connection region 10 may be provided at (e.g., in or on) an upper surface 2_U of the body 2, and another connection region 10 may be provided on the lower surface 2_L of the body 2. In some embodiments, the two connection regions 10 may be overlapping (e.g., completely overlapping) with one another, and may have a same size and/or shape as one another. According to some embodiments, in a plan view (e.g., FIG. 1B), a center of the connection region(s) 10 may overlap with the center of the body 2 in a case where the body 2 has the fundamental unit dimensions.

As shown in FIG. 1B, the body 2 may have a rectangular shape (e.g., a square shape) in a plan view, and/or the connection region(s) 10 may have a rectangular shape (e.g., a square shape) in the plan view. However, embodiments of the present disclosure are not limited thereto. For example, the body 2 and/or the connection region(s) 10 may have various different shapes. Additionally, the body 2 and/or the connection region(s) 10 may have various different sizes.

According to some embodiments, the fundamental unit dimensions may be one or more (e.g., some or all) of the following: (a) a width W1 of the component 1 (or the body 2) in a first horizontal direction (e.g., X-direction); (b) a width W2 of the component 1 (or the body 2) in a second horizontal direction (e.g., Y-direction) crossing (e.g., perpendicular to) the first horizontal direction (e.g., X-direction); and (c) a thickness T of the component 1 (or the body 2) in a vertical direction (e.g., Z-direction) crossing (e.g., perpendicular to) the first horizontal direction (e.g., X-direction) and the second horizontal direction (e.g., Y-direction). According to some embodiments, the width W1 and the width W2 may be equal to one another. However, embodiments of the present disclosure are not limited thereto.

According to some embodiments, the connection region(s) 10 may have a width W3 in the first horizontal direction (e.g., X-direction), and a width W4 in the second horizontal direction (e.g., Y-direction). According to some embodiments, the width W3 and the width W4 may be equal to one another. However, embodiments of the present disclosure are not limited thereto.

According to some embodiments, the component 1 may be referred to as a minimum-sized component (e.g., a minimum-sized semiconductor device or a minimum-sized interposer) of a semiconductor system. For example, the component 1 may be a smallest-sized component that may be included in the semiconductor system, but embodiments of the present disclosure are not limited thereto.

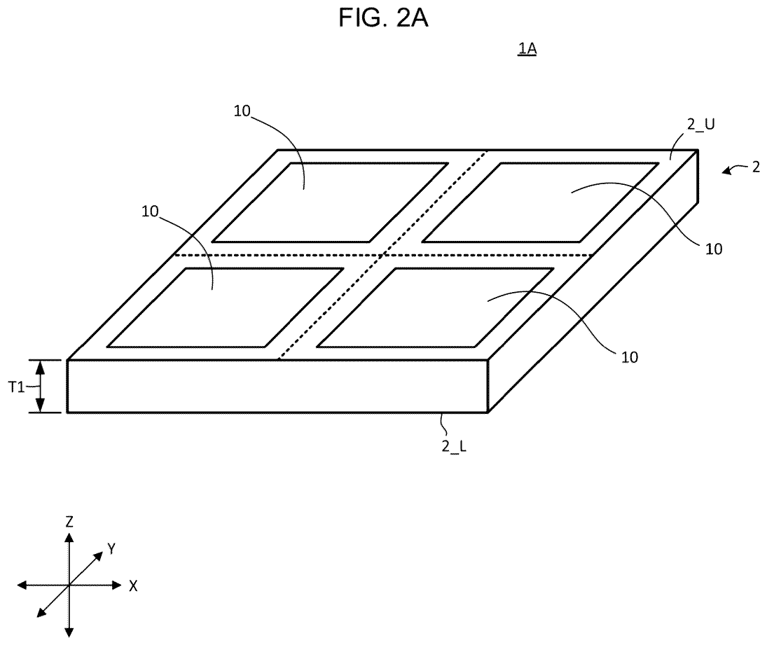

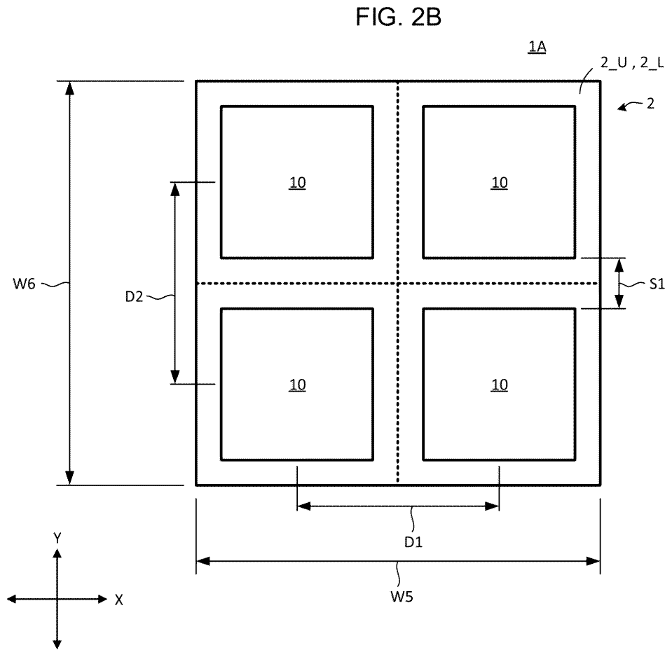

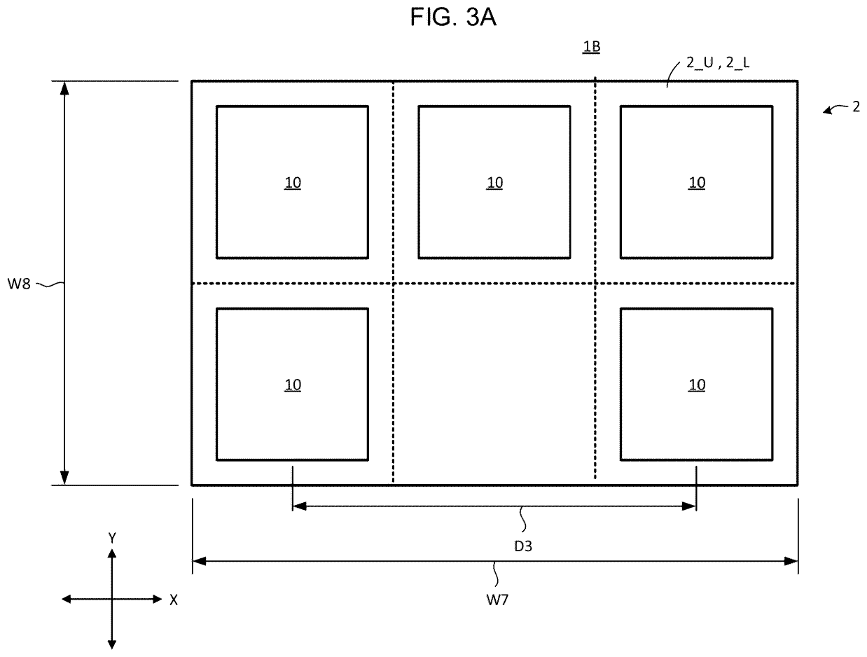

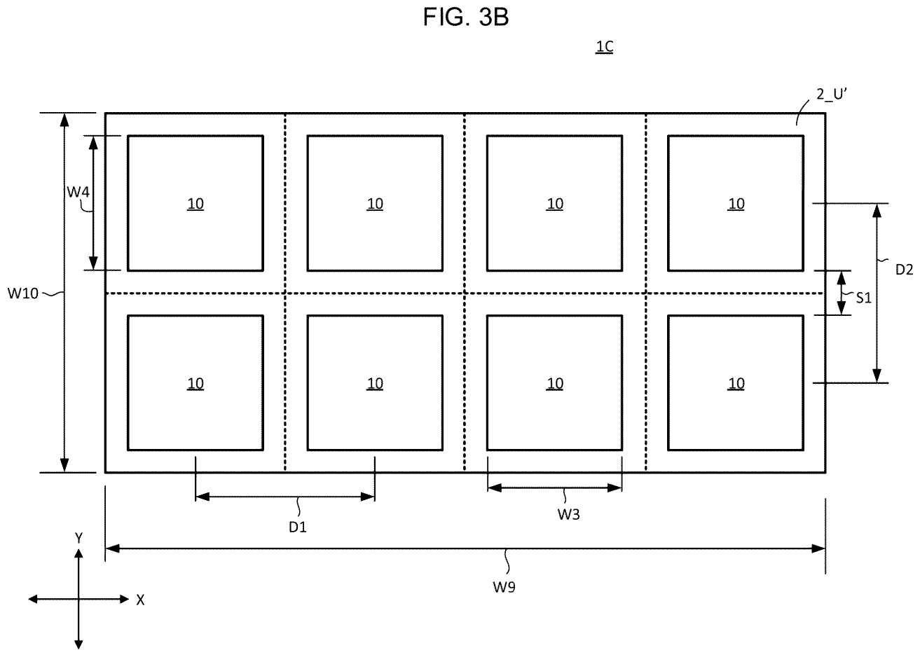

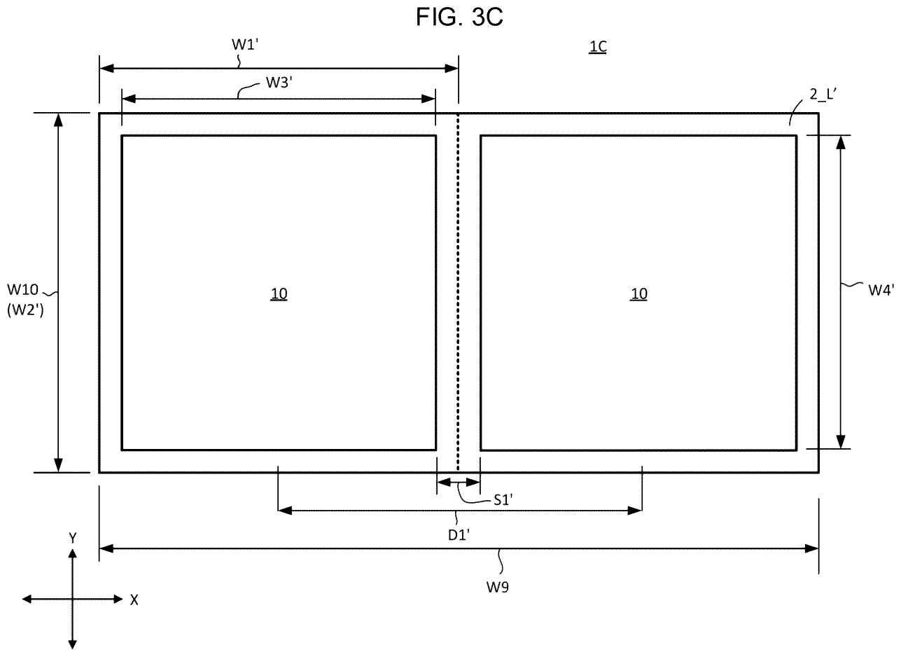

According to some embodiments, one or more of components (e.g., components 1, 1A, 1B, 1C, 110A-110F, 120A-120L, 210, 220, and 310; see FIGS. 1-11) of a semiconductor system may have dimensions that are substantially equal to, or an integer multiple of, dimensions of the fundamental unit. In a case where the components follow modular design rules (e.g., dimensions and/or positions) as described in the present disclosure (e.g., with reference to FIGS. 1-11), the components may be referred to as modular components. Examples of such modular components are described below with reference to FIGS. 2A, 2B, 3A, 3B, and 3C.

According to some embodiments, with reference to FIGS. 2A-2B, one or more modular components (e.g., the component 1A), or a body 2 thereof, may have a width W5 in the first horizontal direction (e.g., X-direction), a width W6 in the second horizontal direction (e.g., Y-direction), and a thickness T1 in the vertical direction (e.g., Z-direction). The width W5 may be substantially equal to, or an integer multiple of, the fundamental unit width W1 (see FIG. 1B); the width W6 may be substantially equal to, or an integer multiple of, the fundamental unit width W2 (see FIG. 1B); and/or the thickness T1 may be substantially equal to, or an integer multiple of, the fundamental unit thickness T (see FIG. 1A).

For example, various modular components (e.g., components 1, 1A, 1B, 1C, 110A-110F, 120A-120L, 210, 220, and 310; see FIGS. 1-11) may have one or more (e.g., some or all) dimensions (e.g., a width in the X-direction, a width in the Y-direction, and/or a thickness in the Z-direction)) that are substantially equal to, or substantially an integer multiple of, the corresponding respective fundamental unit dimension. For example, the various components may have the following non-limiting example configurations:

(a) The width W5 may be substantially equal to the fundamental unit width W1 (see FIG. 1B); the width W6 may be substantially equal to the fundamental unit width W2 (see FIG. 1B); and the thickness T1 may be substantially equal to the fundamental unit thickness T (see FIG. 1A).

(b) The width W5 may be substantially an integer multiple of the fundamental unit width W1 (see FIG. 1B); the width W6 may be substantially equal to the fundamental unit width W2 (see FIG. 1B); and the thickness T1 may be substantially equal to the fundamental unit thickness T (see FIG. 1A).

(c) The width W5 may be substantially an integer multiple of the fundamental unit width W1 (see FIG. 1B); the width W6 may be substantially an integer multiple of the fundamental unit width W2 (see FIG. 1B); and the thickness T1 may be substantially equal to the fundamental unit thickness T (see FIG. 1A).

(d) The width W5 may be substantially an integer multiple of the fundamental unit width W1 (see FIG. 1B); the width W6 may be substantially an integer multiple of the fundamental unit width W2 (see FIG. 1B); and the thickness T1 may be substantially an integer multiple of the fundamental unit thickness T (see FIG. 1A).

(e) The width W5 may be substantially equal to the fundamental unit width W1 (see FIG. 1B); the width W6 may be substantially an integer multiple of the fundamental unit width W2 (see FIG. 1B); and the thickness T1 may be substantially equal to the fundamental unit thickness T (see FIG. 1A).

(f) The width W5 may be substantially equal to the fundamental unit width W1 (see FIG. 1B); the width W6 may be substantially equal to the fundamental unit width W2 (see FIG. 1B); and the thickness T1 may be substantially an integer multiple of the fundamental unit thickness T (see FIG. 1A).

(g) The width W5 may be substantially equal to the fundamental unit width W1 (see FIG. 1B); the width W6 may be substantially an integer multiple of the fundamental unit width W2 (see FIG. 1B); and the thickness T1 may be substantially an integer multiple of the fundamental unit thickness T (see FIG. 1A).

According to some embodiments, when the width W5 is substantially a first integer multiple of the fundamental unit width W1 (see FIG. 1B) and the width W6 is substantially a second integer multiple of the fundamental unit width W2 (see FIG. 1B), the first integer multiple may be the same as or different from the second integer multiple. Additionally, when the thickness T1 is substantially an integer multiple of the fundamental unit thickness T (see FIG. 1A), the integer multiple of the thickness T1 may be substantially the same as or different from the first integer multiple and/or the second integer multiple.

In the disclosure, the phrase “substantially the same” and “substantially equal to” refers to two or more dimensions (or integer multiples) that are either exactly equal or close enough in size such that any differences between them are negligible for the intended purpose or function of embodiments of the present disclosure. Minor variations due to manufacturing tolerances, or other acceptable deviations, are considered within the scope of “substantially the same” and “substantially equal to.” For example, dimensions of two components (or portions thereof) may be deemed “substantially equal” if a difference therebetween are no more than about 5%, provided such a difference does not materially affect their interchangeability, alignment, or functional compatibility in embodiments of the present disclosure. For example, in a case where a width or thickness of a component is substantially an integer multiple of a dimension of the fundamental unit, the width or the thickness of the component may be slightly less than an integer multiple of the dimension of the fundamental unit to account for manufacturing tolerances and/or to ensure that components may be positioned adjacent to one another in a semiconductor system. For example, the width or the thickness of the component may be less than an integer multiple of the dimension of the fundamental unit by up to 5% of the dimension of the fundamental unit. However, embodiments of the present disclosure are not limited thereto.

According to some embodiments, when the width W5 of the component 1A (or the body 2) in the first horizontal direction (e.g., X-direction) is substantially ‘N’ times the fundamental unit width W1 (see FIG. 1B), up to ‘N’ number of columns of the connection regions 10 may be provided at (e.g., in or on) the upper surface 2_U of the component 1A, and/or up to ‘N’ number of columns of the connection regions 10 may be provided at (e.g., in or on) the lower surface 2_L of the component 1A. The columns may extend in the second horizontal direction (e.g., Y-direction) and may be spaced apart from one another in the first horizontal direction (e.g., X-direction).

According to some embodiments, when the width W6 of the component 1A (or the body 2) in the second horizontal direction (e.g., Y-direction) is substantially ‘M’ times the fundamental unit width W2 (see FIG. 1B), up to ‘M’ number of rows of connection regions 10 may be provided at (e.g., in or on) the upper surface 2_U of the component 1A, and/or up to ‘M’ number of rows of connection regions 10 may be provided at (e.g., in or on) the lower surface 2_L of the component 1A. The rows may extend in the first horizontal direction (e.g., X-direction) and may be spaced apart from one another in the second horizontal direction (e.g., Y-direction).

According to some embodiments, in a plan view (e.g., FIG. 2B), the connection regions 10 may be uniformly arranged at (e.g., in or on) the upper surface 2_U and/or at (e.g., in or on) the lower surface 2_L. For example, centers of neighboring ones of the connection regions 10 in the first horizontal direction (e.g., X-direction) may be spaced apart from one another at substantially a distance D1 (which may be substantially equal to the fundamental unit width W1), and centers of neighboring ones of the connection regions 10 in the second horizontal direction (e.g., Y-direction) may be spaced apart from one another at substantially a distance D2 (which may be substantially equal to the fundamental unit width W2). The distance D1 and the distance D2 may be substantially equal to one another. Alternatively or additionally, a distance S1 may be between the neighboring ones of the connection regions 10 in the first horizontal direction (e.g., X-direction) and/or the neighboring ones of the connection regions 10 in the second horizontal direction (e.g., Y-direction). According to some embodiments, the connection regions 10 may be uniformly arranged at (e.g., in or on) the upper surface 2_U and/or at (e.g., in or on) the lower surface 2_L, and the connection regions 10 at (e.g., in or on) the upper surface 2_U may respectively overlap the connection regions 10 at (e.g., in or on) the lower surface 2_L. According to some embodiments, the connection regions 10 may be arranged in an array exhibiting symmetry in the first horizontal direction (e.g., X-direction) and/or the second horizontal direction (e.g., Y-direction). However, embodiments of the present disclosure are not limited thereto.

According to some embodiments, the distance (e.g., the distance D1) between centers of neighboring ones of the connection regions 10 in the first horizontal direction (e.g., X-direction) may be substantially equal to, or an integer multiple of, the fundamental unit width W1 (see FIG. 1B). Alternatively or additionally, the distance (e.g., the distance D2) between centers of neighboring ones of the connection regions 10 in the second horizontal direction (e.g., Y-direction) may be substantially equal to, or an integer multiple of, the fundamental unit width W2 (see FIG. 1B). However, embodiments of the present disclosure are not limited thereto.

According to some embodiments, one or more components (e.g., components 1, 1A, 1B, 1C, 110A-110F, 120A-120L, 210, 220, and 310; see FIGS. 1-11) may have one or more dimensions that do not follow the design rules described above and/or below. As a non-limiting example, such partially non-confirming components may be used for interfacing the SIP system with the exterior world (which may not comply with the dimensional rules and constraints within the SIP). For example, the one or more of the partially non-conforming components may include external sensors, external interfaces, or as adapters between components following two different sets of design rules (as will be discussed below), etc.

FIGS. 2A-2B show an example in which the width W5 in the first horizontal direction (e.g., X-direction) may be substantially two times the fundamental unit width W1 (see FIG. 1B), and the width W6 in the second horizontal direction (e.g., Y-direction) may be substantially two times the fundamental unit width W2 (see FIG. 1B). In such a case, up to two columns and two rows of connection regions 10 may be provided at (e.g., in or on) the upper surface 2_U of the component 1A, and/or up to two columns and two rows of connection regions 10 may be provided at (e.g., in or on) the lower surface 2_L of the component 1A. However, embodiments of the present disclosure are not limited thereto.

FIG. 3A shows an example in which a width W7 in the first horizontal direction (e.g., X-direction) may be substantially three times the fundamental unit width W1 (see FIG. 1B), and a width W8 in the second horizontal direction (e.g., Y-direction) may be substantially two times the fundamental unit width W2 (see FIG. 1B). In such a case, up to three columns and two rows of connection regions 10 may be provided at (e.g., in or on) the upper surface 2_U of the component 1A, and/or up to three columns and two rows of connection regions 10 may be provided at (e.g., in or on) the lower surface 2_L of the component 1A. For example, a total number of columns of the connection regions 10 may be equal to or less than the integer multiple (e.g., 3 times) of the width W1, and the total number of rows of the connection regions 10 may be equal to or less than the integer multiple (e.g., two times) of the width W2. However, embodiments of the present disclosure are not limited thereto.

According to some embodiments, at least one connection region 10 may be omitted such that a distance between centers of two neighboring ones of the connection regions 10 becomes substantially an integer multiple of the distance D1 (see FIG. 2B) and/or the distance D2 (see FIG. 2B). According to embodiments, a spacing between the two neighboring ones of the connection regions 10 may also become substantially an integer multiple of the spacing S1 (see FIG. 2B). However, embodiments of the present disclosure are not limited thereto.

For example, FIG. 3A shows omission of a connection region 10 from a center column, lower row, of the connection regions 10, such that a distance D3 between centers of two neighboring ones of the connection regions 10 in the lower row becomes substantially an integer multiple (e.g., two times) of the distance D1. However, embodiments of the present disclosure are not limited thereto. For example, any number of connection regions 10 may be omitted, and connection regions 10 at various other positions may be omitted.

According to some embodiments, with reference to FIGS. 3B-3C, a configuration of the connection regions 10 at a first surface of the modular component (e.g., components 1, 1A, 1B, 1C, 110A-110F, 120A-120L, 210, 220, and 310; see FIGS. 1-11) may be different from a configuration of the connection regions 10 at a second surface of the modular component. For example, a number and/or size of the connection regions 10, or a distance between the connection regions 10, at the second surface may be different from a number and/or size of the connection regions 10, or a distance between the connection regions 10, at the first surface. For example, the design rules (e.g., dimensions and/or relationships) for the connection regions 10 at the first surface may be different from the design rules (e.g., dimensions and/or relationships) for the connection regions 10 at the second surface.

Accordingly, the modular component may function as a size and/or layout converter to connect components made according to a first set of modular design rules (e.g., size and connection configurations) with components made using a different set of modular design rules (e.g., size and connection configurations). According to some embodiments, by stacking a plurality of modular components that function as size and/or layout converters, multiple stages of size, and/or layout conversions may be provided.

For example, the first surface of the modular component may be configured to be bonded (e.g., electrically connected) to a surface of a first additional modular component due to the connection regions 10 at both surfaces being configured based on the first set of modular design rules. Also, the second surface of the modular component may be configured to be bonded (e.g., electrically connected) to a surface of a second additional modular component based on the connection regions 10 at both surfaces being configured based on the second set of modular design rules.

According to some embodiments, in a modular component, a total number of the connection regions 10 at the first surface may be greater than (e.g., an integer multiple of) a total number of the connection regions 10 at the second surface, and/or a respective size (e.g., width in the X-direction and/or the Y-direction) of the connection regions 10 at the second surface may be greater than (e.g., an integer multiple of) a respective size (e.g., width in the X-direction and/or the Y-direction) of the connection regions 10 at the first surface, such that the component may be configured as a fan out component (e.g., a fan out interposer). An example of such a modular component is described in detail below with reference to FIGS. 3B-3C.

According to some embodiments, with reference to FIGS. 3B-3C, a component 1C (e.g., a modular component) may have a first surface 2_U′ and a second surface 2_L′. The first surface 2_U′ and the second surface 2_L′ may be an upper surface and a lower surface of the component 1C, respectively. However, embodiments of the present disclosure are not-limited thereto. As a non-limiting example, the component 1C is shown to have a width W9 in the first horizontal direction (e.g., X-direction) and a width W10 in the second horizontal direction (e.g., Y-direction).

With reference to FIG. 3B, a configuration of the connection regions 10 at the first surface 2_U′ of the component 1C may follow design rules (hereinafter referred to as first design rules) described in the present disclosure with reference to FIGS. 1-2B. For example, the connection region(s) 10 may have the width W3 in the first horizontal direction (e.g., X-direction) and the width W4 in the second horizontal direction (e.g., Y-direction). Alternatively or additionally, centers of neighboring ones of the connection regions 10 in the first horizontal direction (e.g., X-direction) may be spaced apart from one another at substantially the distance D1 (which may be substantially equal to the fundamental unit width W1), and centers of neighboring ones of the connection regions 10 in the second horizontal direction (e.g., Y-direction) may be spaced apart from one another at substantially the distance D2 (which may be substantially equal to the fundamental unit width W2). Alternatively or additionally, the distance S1 may be between the neighboring ones of the connection regions 10 in the first horizontal direction (e.g., X-direction) and/or the neighboring ones of the connection regions 10 in the second horizontal direction (e.g., Y-direction). In FIG. 3B, eight connection regions 10 are shown to be in two rows of four columns. However, embodiments of the present disclosure are not limited thereto. For example, any number of connections regions 10, and rows and columns thereof, may be provided.

With reference to FIG. 3C, a configuration of the connection regions 10 at the second surface 2_L′ of the component 1C may follow second design rules different from the first design rules. For example, the connection region(s) 10 may have a width W3′ in the first horizontal direction (e.g., X-direction) and a width W4′ in the second horizontal direction (e.g., Y-direction). Alternatively or additionally, centers of neighboring ones of the connection regions 10 in the first horizontal direction (e.g., X-direction) may be spaced apart from one another at substantially a distance D1′ (which may be which may be substantially equal to a fundamental unit width W1′), and centers of neighboring ones of the connection regions 10 in the second horizontal direction (e.g., Y-direction) may be spaced apart from one another at substantially a predetermined distance (which may be substantially equal to a fundamental unit width W2′) that may be substantially the same as or different from the distance D1′. Alternatively or additionally, a distance S1′ may be between the neighboring ones of the connection regions 10 in the first horizontal direction (e.g., X-direction) and/or the neighboring ones of the connection regions 10 in the second horizontal direction (e.g., Y-direction). In FIG. 3C, two connection regions 10 are shown to be in one row of two columns. However, embodiments of the present disclosure are not limited thereto. For example, any number of connections regions 10, and rows and columns thereof, may be provided.

According to some embodiments, one or more (e.g., some or all) of the second design rules (e.g., the width W3′, the width W4′, the distance D1′, the predetermined distance, and/or the distance S1′) may be different from the corresponding first design rules (e.g., the width W3, the width W4, the distance D1, the distance D2, and the distance S1).

According to some embodiments, the dimensions and layout of the connections regions 10 at the second surface 2_L′ may be based on at least one fundamental unit dimension (e.g., a fundamental unit width W1′ and/or a fundamental unit width W2′) in a horizontal direction (e.g., the X-direction and/or the Y-direction) that is different from the corresponding fundamental unit dimension(s) (e.g., the fundamental width W1 and/or the fundamental width W2) from which the dimensions and layout of the connections regions 10 at the first surface 2_L′ are based. For example, one or more (e.g., some or all) of fundamental unit dimensions (e.g., the fundamental unit width W1′ and/or the fundamental unit width W2′), from which the second design rules are based, may substantially be a respective multiple (e.g., integer multiple) of the corresponding fundamental unit dimension (e.g., the fundamental width W1 and/or the fundamental width W2), from which the first design rules are based, so as to provide physical size compatibility between module components based on the first design rules and modular components based on the second design rules. For example, the fundamental unit width W1′ may be substantially two times the fundamental unit width W1. However, embodiments of the present disclosure are not limited thereto.

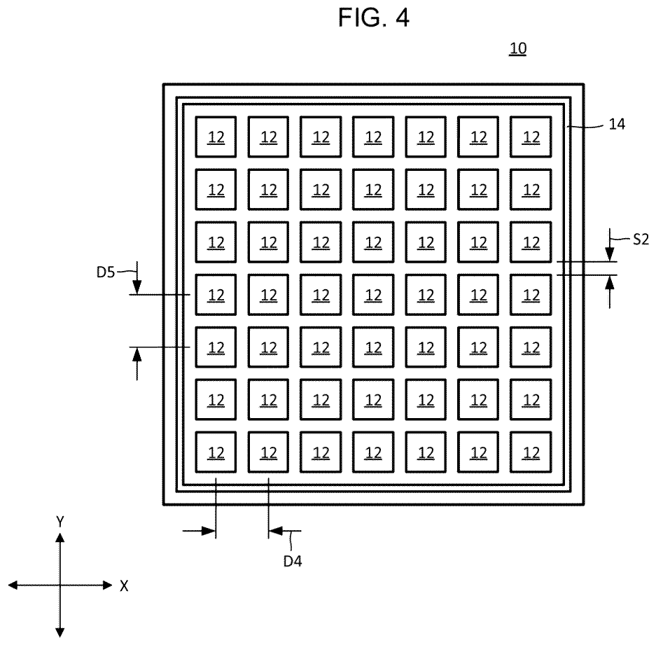

With reference to FIG. 4, an example internal configuration of the connection regions 10 is described below. FIG. 4 illustrates a schematic plan view of a connection region 10 of a component of a semiconductor system for connecting to another component, according to an example embodiment of the present disclosure.

With reference to FIG. 4, the connection regions 10 may respectively include a plurality of interconnectors 12. The plurality of interconnectors 12 of the component (e.g., components 1, 1A, 1B, 1C, 110A-110F, 120A-120L, 210, 220, and 310; see FIGS. 1-11) may be configured to connect (e.g., electrically connect) the component to one or more other components (e.g., components 1, 1A, 1B, 1C, 110A-110F, 120A-120L, 210, 220, and 310; see FIGS. 1-11). For example, one or more (e.g., some or all) of the interconnectors 12 of the component may be configured to transmit (and/or receive) an electrical communication signal or power to (and/or from) one or more other components by being connected to one or more interconnectors 12 of the one or more other components. For example, a first set of the interconnectors 12 of a connection region 10 component may be configured to transmit (and/or receive) an electrical communication signal, and a second set of the interconnectors 12 of the connection region 10 may be configured to transmit (and/or receive) power. However, embodiments of the present disclosure are not limited thereto.

According to some embodiments, the interconnectors 12 may be, for example, bumps (e.g., ubumps), pillars, pads, etc., but embodiments of the present disclosure are not limited thereto. According to some embodiments, the connection regions 10 may include a same number of interconnectors 12 as one another. For example, a connection region 10 may include any number of interconnectors 12, including, for example, thousands of interconnectors 12 (e.g., about 4,000 interconnectors 12). However, embodiments of the present disclosure are not limited thereto.

The interconnectors 12 may have a same size and/or a same shape as one another. For clarity of illustration, the interconnectors 12 are shown in FIG. 14 to have a rectangular (e.g., square) shape in a plan view (e.g., FIG. 4). However, embodiments of the present disclosure are not limited thereto. For example, the interconnectors 12 may have various shapes in a plan view including, for example, a circular shape.

According to some embodiments, in the plan view (e.g., FIG. 4) of the connection region 10, the interconnectors 12 may be uniformly arranged at (e.g., in or on) the upper surface 2_U and/or at (e.g., in or on) the lower surface 2_L of the body 2. For example, centers of neighboring ones of the interconnectors 12 in the first horizontal direction (e.g., X-direction) may be spaced apart from one another at substantially a distance D4, and centers of neighboring ones of the interconnectors 12 in the second horizontal direction (e.g., Y-direction) may be spaced apart from one another at substantially a distance D5. The distance D4 and the distance D5 may be substantially equal to one another. Alternatively or additionally, a distance S2 may be between the neighboring ones of the interconnectors 12 in the first horizontal direction (e.g., X-direction) and/or the neighboring ones of the interconnectors 12 in the second horizontal direction (e.g., Y-direction). According to some embodiments, the interconnectors 12 may be arranged in an array exhibiting symmetry in the first horizontal direction (e.g., X-direction) and/or the second horizontal direction (e.g., Y-direction). For example, according to some embodiments, the interconnectors 12 may be arranged to have four-fold symmetry so that the interconnectors 12 of a connection region 10 of one modular component may be aligned and connected to the interconnectors 12 of a connection region 10 of another modular component, even when the one or other modular component is rotated in increments of 90 degrees.

According to some embodiments, the connection regions 10 may further respectively include a sealing ring 14 surrounding the plurality of interconnectors 12 in the plan view (e.g., FIG. 4). The sealing ring 14 may be configured to protect the interconnectors 12 of the connection region 10 from mechanical stress, moisture, electrostatic discharge (ESD), and/or electromagnetic fields. For example, the sealing ring 14 may include one or more layers including one or more (e.g., some or all) from among a metal(s), an oxide(s), and a passivation material(s). As shown in FIG. 4, the sealing ring 14 may have a rectangular (e.g., a square shape). However, embodiments of the present disclosure are not limited thereto, and the sealing ring 14 may have various other shapes.

According to some embodiments, the connection regions 10 of a component may be connected (e.g., electrically connected) together. For example, one or more (e.g., some or all) interconnectors 12 of one of the connection regions 10 of the component may be connected (e.g., electrically connected) to one or more (e.g., some or all) interconnectors 12 of at least one other connection region 10 of the component. Accordingly, the interconnectors 12 of one connection region 10 of the component may be configured to transmit (and/or receive) an electrical communication signal or power to (and/or from) the one or more other connection regions 10. According to some embodiments, the interconnectors 12 of a connection region 10 may be connected to corresponding interconnectors 12 of at least one other connection region 10 of the component, such that, for example, interconnectors 12 in a same relative location (or relatively symmetric location) within their respective connection regions 10 are connected together. However, embodiments of the present disclosure are not limited thereto.

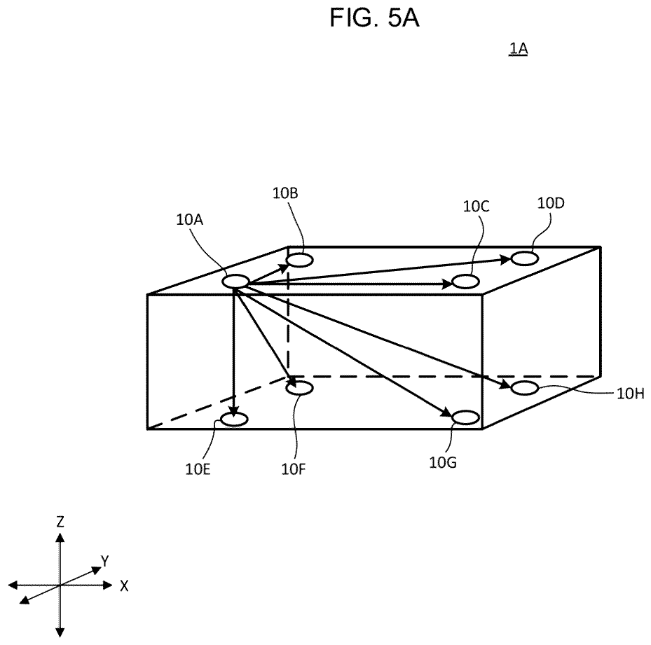

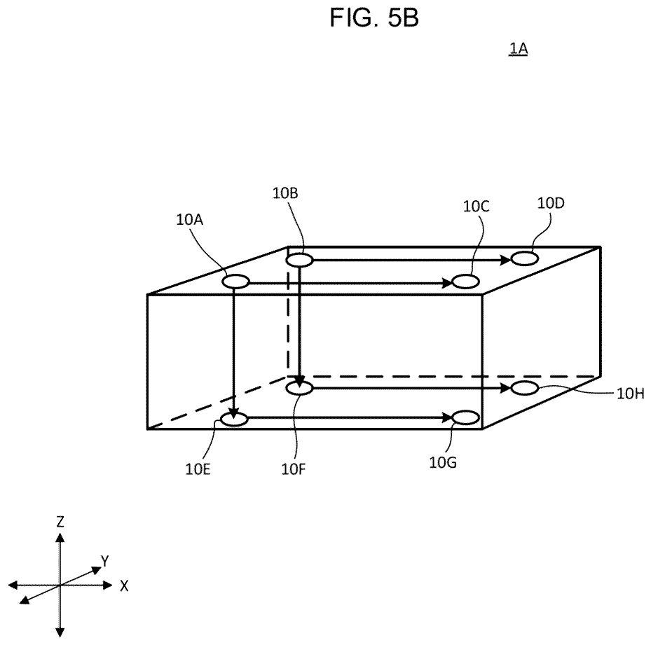

Example connection configurations of the connection regions 10 is described below with reference to FIGS. 5A-B. FIG. 5A illustrates a schematic perspective view showing a first example of interconnections of connection regions 10 of a component 1A (e.g., a modular component), according to an example embodiment of the present disclosure. FIG. 5B illustrates a schematic perspective view showing a second example of interconnections of connection regions 10 of the component 1A, according to an example embodiment of the present disclosure.

With reference to FIG. 5A, a connection region 10 of the component 1A may be directly or indirectly connected (e.g., electrically connected) to all other connection regions 10 of the component 1A. In FIG. 5A, connection configurations of a first connection region 10A from among the connection regions 10 are shown as an example. The connection configurations of other connection regions 10 (e.g., a second connection region 10B, a third connection region 10C, a fourth connection region 10D, a fifth connection region 10E, a sixth connection region 10F, a seventh connection region 10G, and an eighth connection region 10H) of the component 1A may be the same as or similar to the connection configurations of the first connection region 10A. According to some embodiments, one or more of the connection configurations of the connection regions 10 of the component 1A may be substantially different from one or more of the connection configurations of other connection regions 10 of the component 1A.

As shown in FIG. 5A, the first connection region 10A may be connected (e.g., electrically connected) to the second connection region 10B, the third connection region 10C, and the fourth connection region 10D, which may be connection regions 10 at a same surface of the component 1A as the first connection region 10A. For example, the first connection region 10A may be respectively connected to the second connection region 10B, the third connection region 10C, and the fourth connection region 10D by respective conductive pathways (see arrows in FIG. 5A) that include a metal. The respective conductive pathways may include at least one wire and/or at least one via (e.g., a through silicon via (TSV)).

The first connection region 10A may also be connected (e.g., electrically connected) to the fifth connection region 10E, the sixth connection region 10F, the seventh connection region 10G, and the eighth connection region 10H, which may be connection regions 10 at a surface of the component 1A that is different from the surface at which the first connection region 10A is located. For example, the first connection region 10A may be respectively connected to the fifth connection region 10E, the sixth connection region 10F, the seventh connection region 10G, and the eighth connection region 10H by respective conductive pathways that include a metal. The respective conductive pathways may include at least one wire and/or at least one via (e.g., TSV).

According to some embodiments, with reference to FIGS. 4 and 5A, the interconnectors 12 of the connection regions 10 may be configured as respective channels based on their respective positions in a connection region 10. For example, in a case where a connection region 10 includes ‘N’ number of interconnectors 12, the connection region 10 may include ‘N’ number of physical channels, wherein ‘N’ is an integer. According to some embodiments, interconnectors 12 within a same array position in their respective connection regions 10 may be configured as a same channel. In a case where the component (e.g., the component 1A) is configured as an interposer, interconnectors 12 that are configured as a same channel within respective connection regions 10 may be connected (e.g., electrically connected) together. In a case where the component (e.g., the component 1A) is configured as an active component (e.g., an active semiconductor chip), the component may be configured to transfer electrical signals and/or power between different channels, and/or originate data on one or more of the channels. For example, the component may be configured to connect (e.g., electrically connect) together interconnectors 12 that are configured as different channels within respective connection regions 10. However, embodiments of the present disclosure are not limited thereto, and connection configurations of the interconnectors 12 may be variously provided. For example, according to some embodiments, one or more (e.g., some or all) of the interconnectors 12 of one connection region 10 may be respectively connected to one or more other interconnectors 12 of another connection region(s) 10.

According to some embodiments, one or more connections between the connection regions 10 may be disconnected to alter a connection configuration of the component 1A. For example, one or more (e.g., some or all) of the connections between interconnectors 12 of the connection regions 10 may respectively include at least one fuse (e.g., an eFuse), and the fuse(s) of at least one of the connections may be blown to disconnect such connections. However, embodiments of the present disclosure are not limited thereto. According to some embodiments, the component 1A described below with reference to FIG. 5B may be an example of a result of altering a connection configuration of the component 1A shown in FIG. 5A. However, embodiments of the present disclosure are not limited thereto.

With reference to FIG. 5B, the connection regions 10 of the component 1A may be configured to perform communication or power distribution to less than all of the other connection regions 10 of the component 1A. That is, at least one connection region 10 of the component 1A may not be directly or indirectly connected to at least one other connection region 10 of the component 1A. For example, one or more manufacturing processes (e.g., blowing fuses of the component 1A) may be performed to the component 1A to disconnect the at least one connection region 10 of the component 1A from the at least one other connection region 10 of the component 1A. For example, as shown in FIG. 5B, among connection regions 10, the first connection region 10A may only be connected to the third connection region 10C and the fifth connection region 10E, and the second connection region 10B may only be connected to the fourth connection region 10D and the sixth connection region 10F. However, embodiments of the present discourse are not limited thereto, and connections and disconnections may be variously provided.

According to some embodiments, the connections may include respective conductive pathways (see arrows in FIG. 5B) that include a metal. The respective conductive pathways may include at least one wire and/or at least one via (e.g., a through silicon via (TSV)).

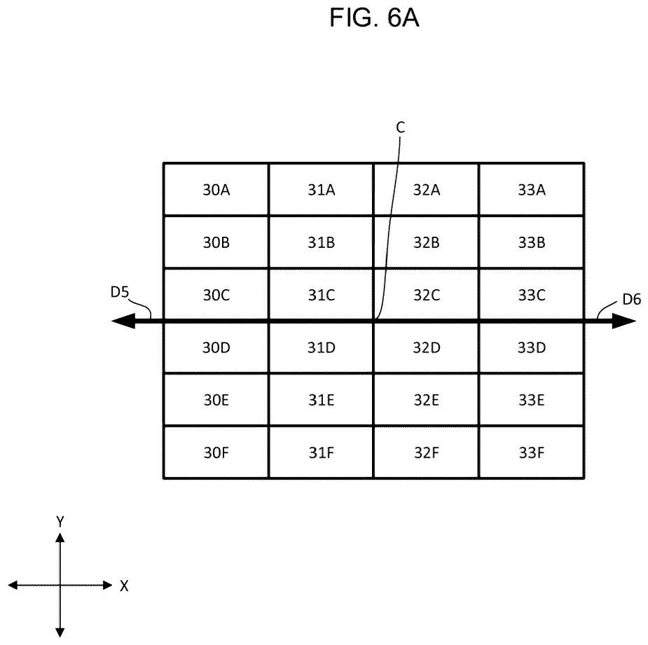

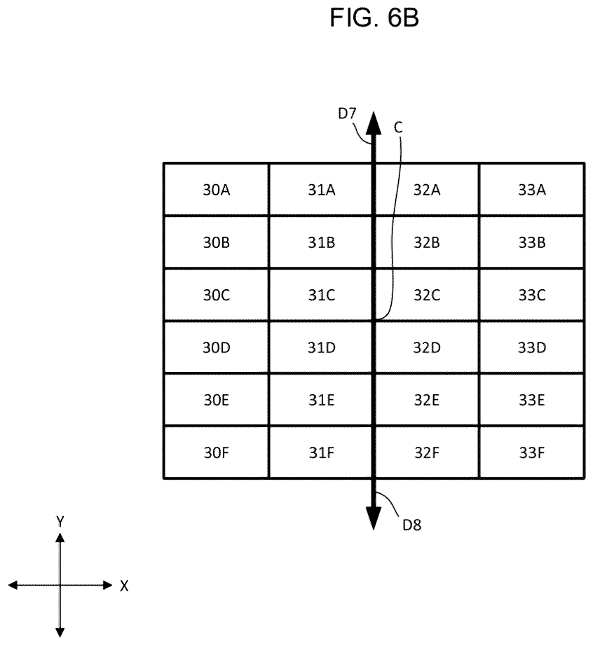

Additional connection configurations of a component (e.g., modular component) are described below with reference to FIGS. 6A-6B. FIGS. 6A-6B respectively illustrate a schematic plan view showing example connections of the component, according to example embodiments of the present disclosure. The plan views of FIGS. 6A-6B may represent a partial or full plan view of a surface (e.g., the upper surface 2_U or the lower surface 2_L (see FIG. 1A)) of the component.

As shown in FIGS. 6A-6B, as a non-limiting, illustrative example, the surface of the component may include four columns of six rows of regions 30A-33F. For example, a first column among the columns may include regions 30A-30F, a second column among the columns may include regions 31A-31F, a third column among the columns may include regions 32A-32F, and a fourth column among the columns may include regions 33A-33F.

According to some embodiments, each of the regions 30A-33F may be a respective connection region 10 (see FIGS. 1-5B) of the component at the surface (e.g., the upper surface 2_U or the lower surface 2_L (see FIG. 1A)) of the component. For example, FIGS. 6A-6B may represent an embodiment in which the component includes 24 connection regions 10 (i.e., six rows of four columns) at the surface. However, embodiments of the present disclosure are not limited thereto, and the surface(s) of the component may include any number of connection regions 10. Additionally, the shapes and sizes of the regions 30A-33F are not limited to the shapes and sizes shown in FIGS. 6A-C. For example, the regions 30A-33F may respectively have other shapes (e.g., a square shape) and/or other sizes. Additionally, according to some embodiments, one or more of the regions 30A-33F (e.g., the connection regions 10) may be omitted.

With reference to FIGS. 6A-6B, the interconnectors 12 of the connector regions 10 may be routed (e.g., electrically connected) to other interconnectors 12 of the connector regions 10 based on at least one line of symmetry. For example, the interconnectors 12 of the connector regions 10 on one side of the at least one line of symmetry may be respectively routed (e.g., electrically connected) to a mirror-image interconnector 12 of a mirror-image connector region 10 on the other side of the at least one line of symmetry.

As shown in FIG. 6A, a line of symmetry extending in the directions D5 and D6 (e.g., X-direction) and crossing through the center C of the surface of the component may be provided. In such case, the interconnectors 12 of the connector regions 10 (e.g., regions 30A-30C, 31A-31C, 32A-32C, and 33A-33C) on an upper side of the line of symmetry may be respectively routed (e.g., electrically connected) to a mirror-image interconnector 12 of a mirror-image connector region 10 (e.g., one of regions 30D-30F, 31D-31F, 32D-32F, and 33D-33F) on the lower side of the line of symmetry.

As shown in FIG. 6B, a line of symmetry extending in the directions D7 and D8 (e.g., Y-direction) and crossing through the center C of the surface of the component may be provided. In such case, the interconnectors 12 of the connector regions 10 (e.g., regions 30A-30F and 31A-31F) on a left side of the line of symmetry may be respectively routed (e.g., electrically connected) to a mirror-image interconnector 12 of a mirror-image connector region 10 (e.g., one of regions 32A-32F and 33A-33F) on the right of the line of symmetry.

According to some embodiments, a plurality of lines of symmetry may be provided. For example, the line of symmetry extending in the X-direction (e.g., FIG. 6A) and the line of symmetry extending in the Y-direction (e.g., FIG. 6B) may be simultaneously provided such that interconnectors 12 have routings to a respective interconnector 12 mirrored towards an opposite corner of the component. For example, an interconnector 12 in region 30B may be routed to a mirror-image interconnector 12 in region 33E.

According to some embodiments, subsets of the interconnectors 12 in one or more (e.g., some or all) connector regions 10 may routed (e.g., electrically connected) based on different symmetries (e.g., a subset in the X-direction, a second subset in the Y-direction, and a third subset X and Y-direction symmetry described above), respectively.

According to embodiments, various semiconductor systems (e.g., semiconductor packages) may be provided in which a plurality of components (e.g., modular components) may be arranged and connected (e.g., electrically connected) together in various configurations. For example, in view of dimensions and/or relationships of the components (e.g., modular components) and their connection regions conforming with design rules as described in the present disclosure, the components (e.g., modular components) may be arranged and connected in various positions in the horizontal directions (e.g., the X-direction and/or the Y-direction) and/or vertical direction (e.g., Z-direction) relative to one another, and have various rotational orientations relative to one another. One or more (e.g., some or all) of the components of such semiconductor packages may have the configurations described above with references to FIGS. 1A-6B, and thus repeated descriptions thereof may be omitted.

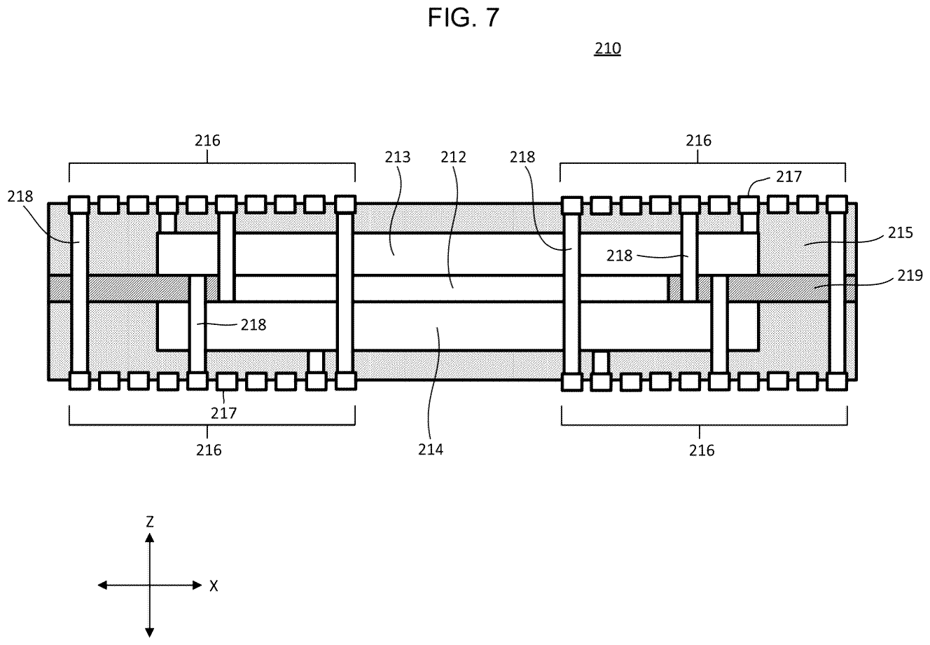

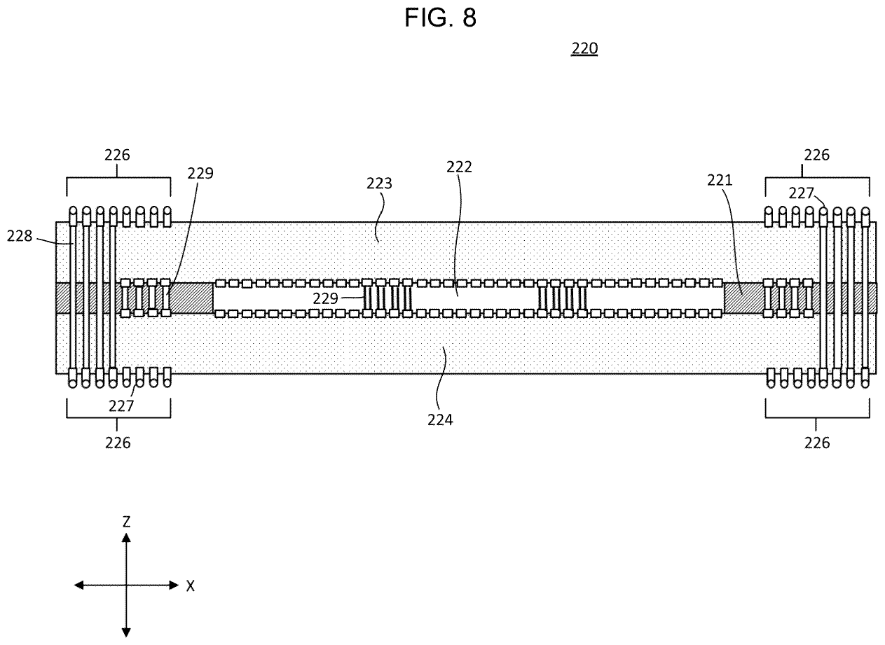

According to some embodiments, the components (e.g., modular components) may be semiconductor devices (e.g., semiconductor chips or semiconductor packages) with various configurations. Non-limiting example configurations of the components (e.g., modular components) are described below with reference to FIGS. 7-8. FIG. 7 illustrates a schematic cross-sectional view showing a semiconductor device 210 including an integrated circuit, according to an example embodiment of the present disclosure. FIG. 8 illustrates a schematic cross-sectional view showing a semiconductor device 220 including an integrated circuit and interposers, according to an example embodiment of the present disclosure. The semiconductor device 210 and the semiconductor device 220 may be examples of modular components described above with reference to FIGS. 1A-6B.

With reference to FIG. 7, the semiconductor device 210 may include, for example, an integrated circuit region 212, a front side (FS) distribution layer 213, a back side (BS) distribution layer 214, a first insulator region 215, connection regions 216, vias 218, and a second insulator region 219.

The integrated circuit region 212 may be an active region including at least one integrated circuit (IC) that is configured to perform a function (e.g., processing or memory) of the semiconductor device 210. For example, the integrated circuit region 212 may be or include a core transistor region that includes at least one transistor.

The FS distribution layer 213 may be on one surface (e.g., an upper surface) of the integrated circuit region 212 and connected (e.g., electrically connected) to the integrated circuit region 212. The BS distribution layer 214 may be on an opposite surface (e.g., a lower surface) of the integrated circuit region 212 and connected (e.g., electrically connected) to the integrated circuit region 212. According to some embodiments, the FS distribution layer 213 may include at least one conductive pathway that is configured to distribute a signal(s) to and/or from the integrated circuit region 212. According to some embodiments, the BS distribution layer 214 may include at least one conductive pathway that is configured to distribute power to and/or from the integrated circuit region 212. For example, the FS distribution layer 213 may be an FS signal distribution network, and the BS distribution layer 214 may be a BS power distribution network (BPSDN). According to some embodiments, the at least one conductive pathway of the FS distribution layer 213 and/or the BS distribution layer 214 may include a conductive material (e.g., a metal). According to some embodiments, the FS distribution layer 213 and/or the BS distribution layer 214 may be omitted.

The first insulator region 215 may at least partially surround the integrated circuit region 212, the FS distribution layer 213, and/or the BS distribution layer 214. For example, the first insulator region 215 may surround upper and lower surfaces of the integrated circuit region 212, upper and side surfaces of the FS distribution layer 213, and/or lower and side surfaces of the BS distribution layer 214. The first insulator region 215 may include an insulating material that is configured to electrically insulate the integrated circuit region 212, the FS distribution layer 213, and/or the BS distribution layer 214. For example, the first insulator region 215 may include a bulk insulator (e.g., bulk silicon), a molding, or a fill. The first insulator region 215 may be provided to cause the semiconductor device 210 to have a first width substantially equal to, or an integer multiple of, the fundamental unit width W1 (see FIG. 1B); a second width substantially equal to, or an integer multiple of, the fundamental unit width W2 (see FIG. 1B); and/or a thicknesses substantially equal to, or an integer multiple of, the fundamental unit thickness T (see FIG. 1A). By including the first insulator region 215, an amount of external connections (e.g., connection regions 216 and/or interconnectors 217 of the connection regions 216) of the semiconductor device 210 may be increased, and/or an amount or size of front and/or back routing structures of the semiconductor device 210 may be increased, thereby increasing bandwidth of the semiconductor device 210. Additionally, by including the first insulator region 215, the connection regions 216 and their interconnectors 217 may be appropriately constructed to follow the spacing and dimension rules described above with reference to FIGS. 1A-6B, rather than their spacing and dimensions being dictated by the size of the integrated circuit region 212 or a component (e.g., active component) thereof.

At least one connection region 216 may be provided at (e.g., in or on) upper and/or lower surfaces of the semiconductor device 210. For example, a plurality of connection regions 216 may be provided at (e.g., in or on) the upper and lower surfaces of the first insulator region 215. The connection regions 216 may respectively be the connection regions 10 described above with reference to FIGS. 1A-4. The connection regions 216 may include interconnectors 217, and the interconnectors 217 may respectively be the interconnectors 12 described above with reference to FIG. 4. The number and shapes of the connection regions 216 and their interconnectors 217 are not limited to the number and shapes shown in FIG. 7.

The vias 218 may respectively connect (e.g., electrically connect) at least one of the interconnectors 217 to at least one from among another interconnector 217 at an opposite surface of the semiconductor device 210, the integrated circuit region 212, the FS distribution layer 213, and the BS distribution layer 214. The vias 218 may include a conductive material (e.g., a metal), and may be, for example, TSVs.

The second insulator region 219 may surround the integrated circuit region 212 in at least one horizontal direction (e.g., the X-direction and/or the Y-direction). The second insulator region 219 may be surrounded in the vertical direction (e.g., the Z-direction) by the first insulator region 215, the FS distribution layer 213, and/or the BS distribution layer 214, and one or more of the vias 218 may penetrate through the second insulator region 219. The second insulator region 219 may include an insulating material that is configured to electrically insulate the integrated circuit region 212, the FS distribution layer 213, and/or the BS distribution layer 214. According to some embodiments, the second insulator region 219 may include a same or different material from the material of the first insulator region 215. According to some embodiments, the second insulator region 219 may include bulk silicon.

With reference to FIG. 8, the semiconductor device 220 may include, for example, an integrated circuit device 222, a first adapter die 223, a second adapter die 224, connection regions 226, first vias 228, second vias 229, and an insulator region 221.

The integrated circuit device 222 may include, for example, an integrated circuit. For example, the integrated circuit device 222 may be or include a semiconductor chip configured to perform a function (e.g., processing or memory). Although FIG. 8 illustrates the integrated circuit device 222 as a single layer, embodiments of the present disclosure are not limited thereto. For example, the integrated circuit device 222 may include a plurality of layers. According to some embodiments, the integrated circuit device 222 may be or include an HBM. However, embodiments of the present disclosure are not limited thereto.

The first adapter die 223 may be on one surface (e.g., an upper surface) of the integrated circuit device 222 and connected (e.g., electrically connected) to the integrated circuit device 222. The second adapter die 224 may be on an opposite surface (e.g., a lower surface) of the integrated circuit device 222 and connected (e.g., electrically connected) to the integrated circuit device 222. According to some embodiments, the first adapter die 223 may include at least one conductive pathway that is configured to distribute a signal(s) or power between two or more (including all) from among the integrated circuit device 222, the second adapter die 224 through the second vias 229, interconnectors 227 of the connection regions 226 at the first adapter die 223, and the interconnectors 227 of the connection regions 226 at the second adapter die 224 through the first vias 228. According to some embodiments, the second adapter die 224 may include at least one conductive pathway that is configured to distribute a signal(s) and/or power between two or more (including all) from among the integrated circuit device 222, the first adapter die 223 through the second vias 229, interconnectors 227 of the connection regions 226 at the second adapter die 224, and the interconnectors 227 of the connection regions 226 at the first adapter die 223 through the first vias 228.

According to some embodiments, the semiconductor device 220 may be configured as a device for adapting the integrated circuit device 222 to a standardized size (e.g., substantially equal to or an integer multiple of dimensions of the fundamental units for each axis). For example, by including the first adapter die 223 and/or the second adapter die 224, the semiconductor device 220 may have a first width substantially equal to, or an integer multiple of, the fundamental unit width W1 (see FIG. 1B); a second width substantially equal to, or an integer multiple of, the fundamental unit width W2 (see FIG. 1B); and/or a thicknesses substantially equal to, or an integer multiple of, the fundamental unit thickness T (see FIG. 1A). For example, the first adapter die 223 may have a first thickness, the integrated circuit device 222 may have a second thickness, and the second adapter die 224 may have a third thickness. Based on the second thickness of the integrated circuit device 222, the first thickness of the first adapter die 223 and the third thickness of the of the second adapter die 224 may be variously selected such that the sum of the first thickness, the second thickness, and the third thickness substantially equals, or is an integer multiple of, the fundamental unit thickness T (see FIG. 1A). According to embodiments, the first thickness, the second thickness, and the third thickness may be substantially the same as or different from one another, provided they sum to substantially T1 or an integer multiple thereof.

By including the first adapter die 223 and/or the second adapter die 224, an amount and arrangement of external connections (e.g., connection regions 226 and/or interconnectors 227 of the connection regions 226) of the semiconductor device 220 may be increased in comparison to the integrated circuit device 222, and/or an amount and/or size of front and/or back routing structures of the semiconductor device 210 may be increased in comparison to the integrated circuit device 222, thereby increasing bandwidth of the semiconductor device 220. Additionally, by including the first adapter die 223 and/or the second adapter die 224, the connection regions 226 and their interconnectors 227 may be appropriately constructed to follow the spacing and dimension rules described above with reference to FIGS. 1A-6B (EG, to form external connection regions 10 and with interconnects 12), rather than their spacing and dimensions being dictated by the size of the integrated circuit device 222.

At least one connection region 226 may be provided at (e.g., in or on) upper and/or lower surfaces of the semiconductor device 220. For example, a plurality of connection regions 226 may be provided at (e.g., in or on) the upper surface of the first adapter die 223 and/or the lower surface of the second adapter die 224. The connection regions 226 may respectively be the connection regions 10 described above with reference to FIGS. 1A-4. The connection regions 226 may include interconnectors 227, and the interconnectors 227 may respectively be the interconnectors 12 described above with reference to FIG. 4. The number and shapes of the connection regions 226 and their interconnectors 227 are not limited to the number and shapes shown in FIG. 8.

The first vias 228 may respectively connect (e.g., electrically connect) at least one of the interconnectors 227 to at least one from among another interconnector 227 at an opposite surface of the semiconductor device 210. The second vias 229 may respectively connect (e.g., electrically connect) the first adapter die 223 to the second adapter die 224, as discussed above. At least one of the second vias 229 may be included in the integrated circuit device 222. Alternatively or additionally, at least one of the second vias 229 may be included outside of the integrated circuit device 222, at an outer periphery region of the integrated circuit device 222 in the first horizontal direction (e.g., X-direction) and/or the second horizontal direction (e.g., Y-direction). For example, at the outer periphery region, at least one of the second vias 229 may penetrate through the insulator region 221. The first vias 228 and the second vias 229 may include a conductive material (e.g., a metal) and may be, for example, TSVs. According to some embodiments, the first adapter die 223 and/or the second adapter die 224 may include various materials including, for example, silicon, glass, and/or an organic material. However, embodiments of the present disclosure are not limited thereto.

The insulator region 221 may surround the integrated circuit device 222 in at least one horizontal direction (e.g., the X-direction and/or the Y-direction) to fill a space between the first adapter die 223 and the second adapter die 224 in which the integrated circuit device 222 is not provided. The second insulator region 221 may include an insulating material that is configured to electrically insulate the integrated circuit device 222. According to some embodiments, the insulator region 221 may include a bulk insulator (e.g., bulk silicon), a molding, or a fill.

As described above, one or more of the components (e.g., modular components) included in the semiconductor systems may be a semiconductor device(s) (e.g., semiconductor chips or semiconductor packages) with various configurations. Alternatively or additionally, one or more of the components (e.g., modular components) included in the semiconductor systems may be an interposer(s). The interposers may have various configurations and functions. For example, the interposers may be configured as a power interposer that is configured to provide power conditioning (e.g., changing voltage, frequency, etc.) and power delivery (e.g., by vertical and/or horizontal routing), an instrumentation interposer that includes a sensor (e.g., a thermometer, voltmeter, etc. ,) configured to sense an attribute (e.g., temperature, voltage, etc.,) within the semiconductor system, a thermal interposer configured to remove heat from the semiconductor system, and/or any other type of interposer. According to some embodiments, at least one of the interposers may be configured as two or more from among the power interposer, the instrumentation interposer, the thermal interposer, and/or the other type(s) of interposers. According to some embodiments, the interposers may be active interposers or passive interposers. According to some embodiments, the interposers may include various materials including, for example, silicon, glass, and/or an organic material. According to some embodiments, the interposers may be provided as one or more of the components (e.g., components 1, 1A, 1B, 1C, 110A-110F, 120A-120L, 210, 220, and 310; see FIGS. 1-11) described in the present disclosure. However, embodiments of the present disclosure are not limited thereto.

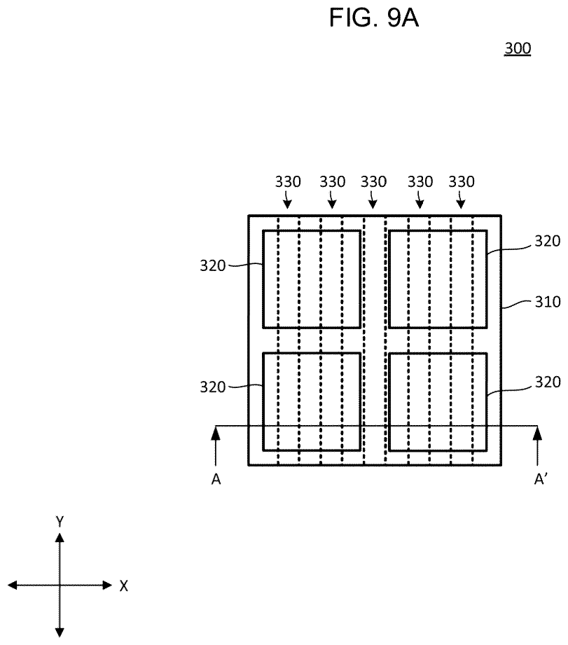

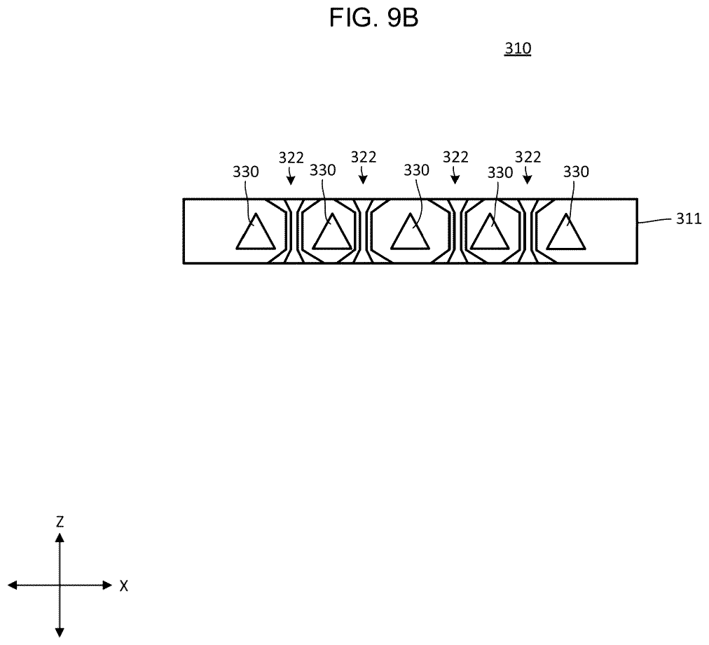

An example of an interposer 300 that is configured to perform routing of signal(s) and/or power and removal of heat is described below with reference to FIGS. 9A-B. FIG. 9A is a schematic plan view showing the interposer 300 of a semiconductor system, according to an example embodiment of the present disclosure. FIG. 9B illustrates a schematic cross-sectional view of the interposer 300, along a line A-A′ of FIG. 9A, according to an example embodiment of the present disclosure.

With reference to FIGS. 9A-9B, the interposer 300 may include a body 310, connection regions 320, and cooling channels 330.

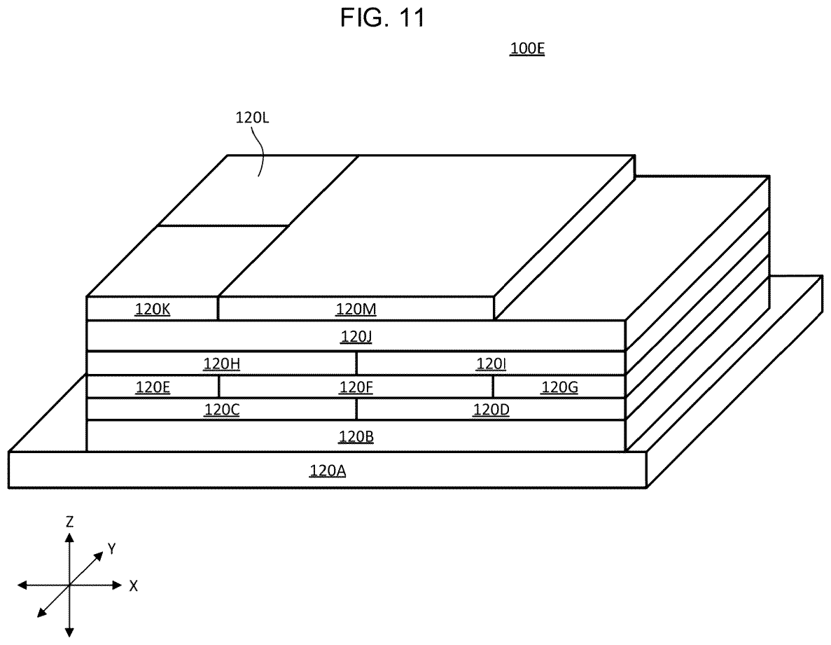

The body 310 may be formed of, for example, silicon, glass, and/or an organic material. The body 310 may define an overall shape and/or size of the interposer 300. For example, the body 310 (or the interposer 300) may have widths substantially equal to, or an integer multiple of, the fundamental unit width W1 (see FIG. 1B) and/or the fundamental unit width W2 (see FIG. 1B), respectively. According to some embodiments, the body 310 (or the interposer 300) may have a thickness substantially equal to, or an integer multiple of, the fundamental unit thickness T (see FIG. 1A). According to some embodiments, the shape and/or size of the interposer is not limited to the shape and/or size shown in FIGS. 11A-B.

The connection regions 320 may be configured to transmit electrical signals and/or power to and/or from components above and/or below the interposer 300. For example, the connection regions 320 may include electrical pathway structures 322. The electrical pathway structures 322 may include a conductive material (e.g., metal). For example, the electrical pathway structures 322 may include vias (e.g., TSVs) and/or interconnectors of the connection regions 320. According to some embodiments, the electrical pathway structures 322 may be configured to provide vertical routing and/or horizontal routing of the electrical signals and/or power to at least two of the connection regions 320, at an upper and/or lower surface of the body 310. According to some embodiments, the connection regions 320 may respectively be the connection regions 10 described above with reference to FIGS. 1A-4. The connection regions 320 may include external terminals of the electrical pathway structures 322, which may respectively be the interconnectors 12 described above with reference to FIG. 4. The number and shapes of the connection regions 320, and their electrical pathway structures 322, are not limited to the number and shapes shown in FIGS. 9A-B.

The cooling channels 330 may be configured to remove heat from of a semiconductor system in which the interposer 300 is provided. For example, the cooling channels 330 may be configured to, by removing heat, cool other components of the semiconductor system that are adjacent to the interposer 300. According to some embodiments, the cooling channels 330 may extend in one horizontal direction, being spaced apart from each other in the other horizontal direction. In one example, as shown in FIGS. 9A-B, the cooling channels 330 may extend in the second horizontal direction (e.g., Y-direction), and may be spaced apart from one another in the first horizontal direction (e.g., X-direction). However, embodiments of the present disclosure are not limited thereto. For example, the cooling channels 330 may extend and/or be spaced apart in various directions, including horizontal and/or vertical directions. According to some embodiments, the cooling channels 330 may have various sizes and shapes, and are not limited to the sizes and shapes shown in FIGS. 9A-B.

According to some embodiments, the cooling channels 330 may include micro heat pipes or micro channels that are configured to receive a cooling fluid. According to some embodiments, the body 310 of the interposer 300 may be in contact with a heat sink, and may be configured to transfer heat from the cooling channels 330 to the heat sink to cool the semiconductor system (e.g., through the movement of a cooling fluid).

According to some embodiments, the interposer 300 may be configured as a modular component by following the design rules as described in the present disclosure.

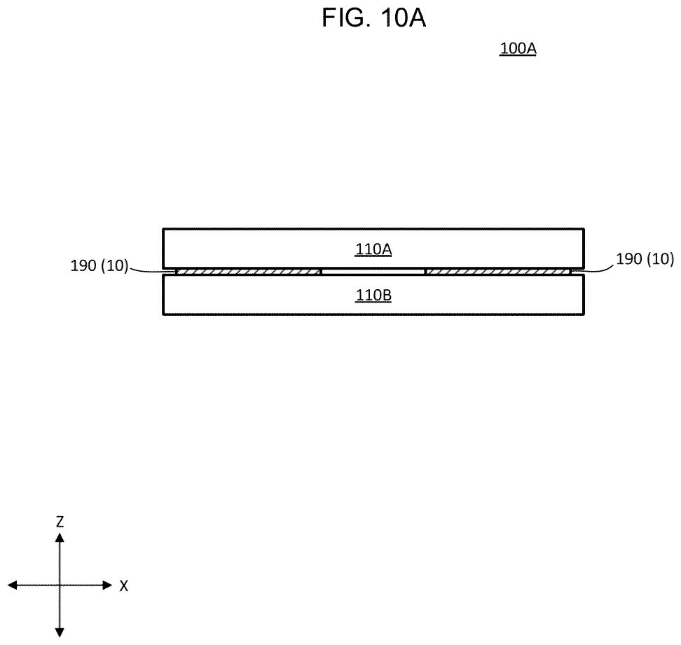

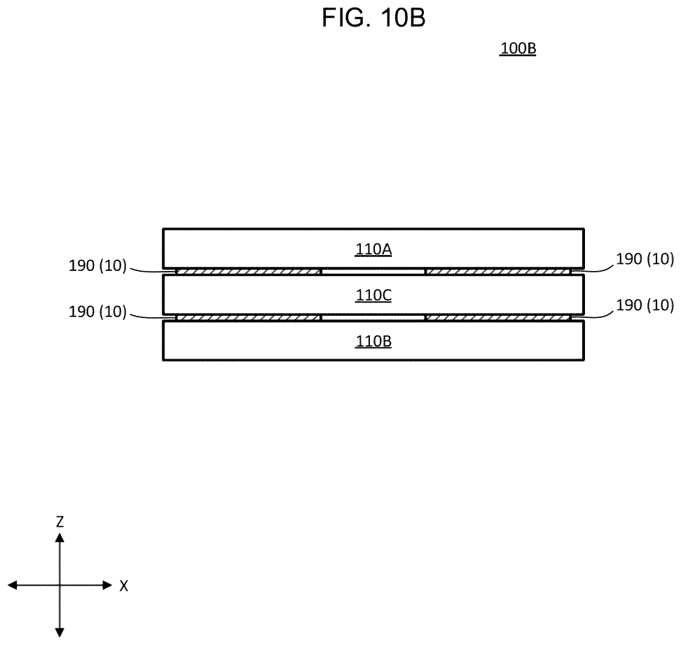

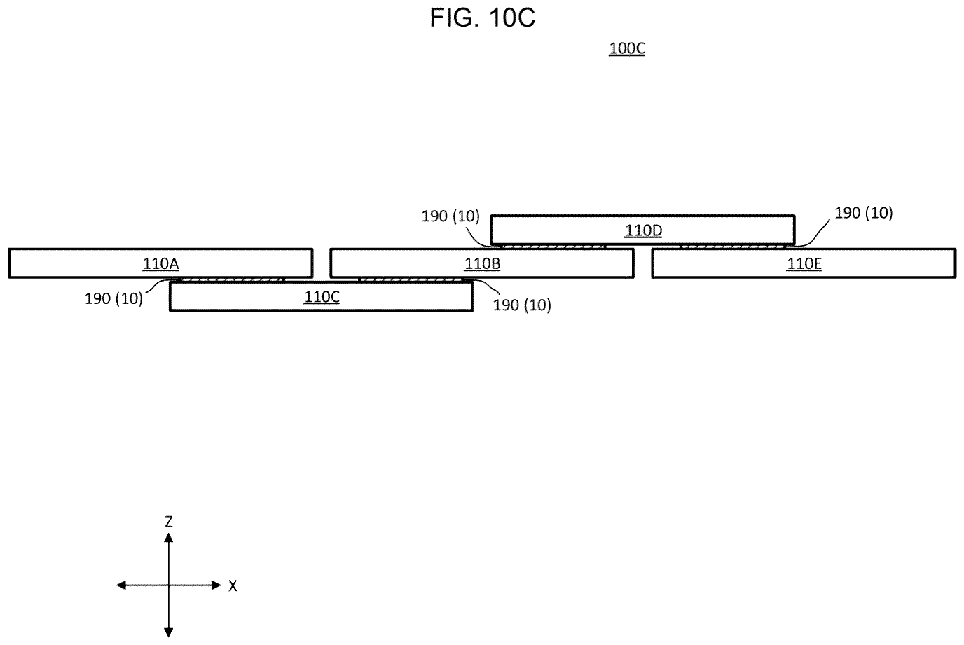

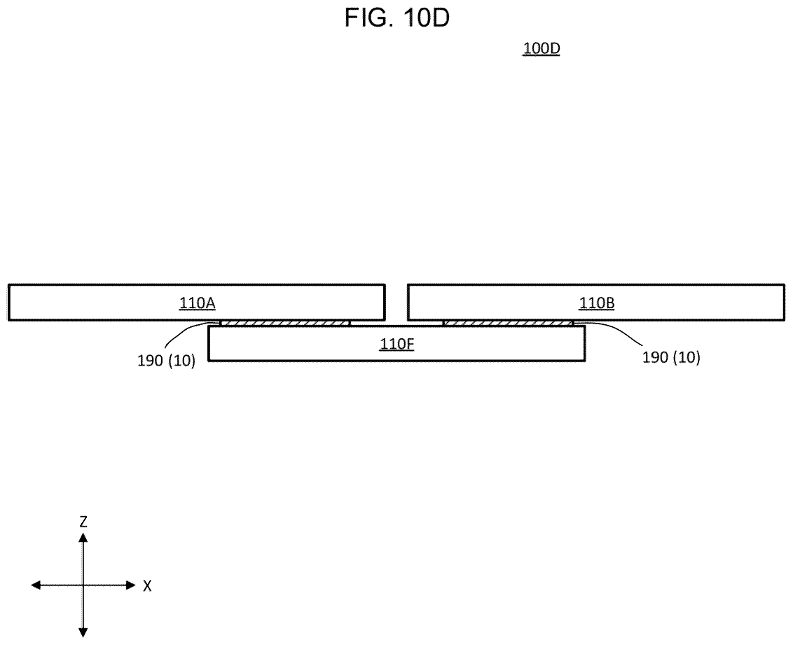

Examples of various semiconductor systems are described below with reference to FIGS. 10A-10D and 11. FIG. 10A illustrates a schematic side view showing a semiconductor system 100A including a vertical stack of two components (e.g., modular components), according to an example embodiment of the present disclosure. FIG. 10B illustrates a schematic side view showing a semiconductor system 100B including a vertical stack of three components (e.g., modular components), according to an example embodiment of the present disclosure. FIG. 10C illustrates a schematic side view showing a semiconductor system 100C including a stack of components (e.g., modular components), including interposers, according to an example embodiment of the present disclosure. FIG. 10D illustrates a schematic side view showing a semiconductor system 100D including a stack of active semiconductor components, according to an example embodiment of the present disclosure. FIG. 11 illustrates a schematic perspective view showing a semiconductor system 100E including various components (e.g., modular components) having different functions and sizes, according to an example embodiment of the present disclosure

With reference to FIG. 10A, the semiconductor system 100A may include two modular components that are vertically stacked and connected (e.g., electrically connected) together. For example, a first component 110A (e.g., modular component) may be vertically stacked on a second component 110B (e.g., modular component), and may be connected (e.g., electrically connected) to the second component 110B by at least one connection 190. The connections 190 may be respective bonds (e.g., an electrical connection) between connection regions 10 (see FIGS. 1A-5B) of the components. For example, one connection 190 may be a bond between a connection region 10 of the first component 110A and a corresponding connection region 10 of the second component 110B. For example, one connection 190 may include bonds (e.g., electrical connections) between the interconnectors 12 (see FIG. 4) of a connection region 10 of the first component 110A and the interconnectors 12 of a corresponding connection region 10 of the second component 110B, such that communication or power may be provided through the connections 190 to the first component 110A from the second component 110B, and/or to the second component 110B from the first component 110A. For example, the bonds may include a metal-to-metal bond between the interconnectors 12 (see FIG. 4) of the respective connection regions 10. According to some embodiments, with reference to FIG. 4, the bonds may include a bond between the sealing rings 14 of the respective connection regions 10. However, embodiments of the present disclosure are not limited thereto.

According to some embodiments, the first component 110A and the second component 110B may be or include active semiconductor component (e.g., active semiconductor chip), respectively. For example, the active semiconductor component may refer to a component that is configured to generate, store, or process data. According to some embodiments, the first component 110A and the second component 110B may be or include a same type or different types of active semiconductor chip with respect to one another.

With reference to FIG. 10B, a semiconductor system 100B may include three modular components that are vertically stacked and connected (e.g., electrically connected) together. For example, a third component 110C (e.g., a modular component) may be vertically stacked on the second component 110B, and may be connected (e.g., electrically connected) to the second component 110B by at least one connection 190. Additionally, the first component 110A may be vertically stacked on the third component 110C, and may be connected (e.g., electrically connected) to the third component 110C by at least one connection 190. According to some embodiments, the third component 110C may be an interposer or may be a functional die including an active semiconductor component.

According to some embodiments, the third component 110C may be configured to connect (e.g., electrically connect) other components. For example, in the configuration shown in FIG. 10B, the third component 110C may connect (e.g., electrically connect) together the first component 110A and the second component 110B through the connections 190, such that communication or power may be provided, through the third component 110C, to the first component 110A from the second component 110B, and/or to the second component 110B from the first component 110A. For example, the third component 110C may be or include a vertical interposer that is configured to perform vertical routing.

With reference to FIG. 10C, a semiconductor system 100C may include one or more modular components that are configured to connect (e.g., electrically connect) a plurality of active semiconductor components that are arranged in one or more directions with respect to one another. For example, the semiconductor system 100C may include the first component 110A, the second component 110B, and a fifth component 110E (e.g., a modular component) that are horizontally arranged (e.g., in the X-direction) with respect to one another. The first component 110A, the second component 110B, and the fifth component 110E may be at a same vertical level (e.g., in the Z-direction).

The semiconductor system 100C may further include the third component 110C and a fourth component 110D (e.g., a modular component). For example, the first component 110A and the second component 110B may be vertically stacked on the third component 110C in such a manner that portions each of first component 110A and the second component 110B may overlap respective portions of the third component 110C, and may be connected (e.g., electrically connected) to respective overlapped portions of an upper surface of the third component 110C by at least one connection 190. Additionally, the fourth component 110D may be vertically stacked on the second component 110B and the fifth component 110E, in such a manner that component 110D overlaps a portion of the second component 110B and the fifth component 110E, and the second component 110B and the fifth component 110E may be connected (e.g., electrically connected) to respective overlapped portions of a lower surface of the fourth component 110D by at least one connection 190.

According to some embodiments, the third component 110C and/or the fourth component 110D may respectively be or include an interposer that is configured to connect (e.g., electrically connect) other components, and/or may be a functional die including an active semiconductor component. For example, in the configuration shown in FIG. 10C, the third component 110C may connect (e.g., electrically connect) together the first component 110A and the second component 110B through the connections 190, such that communication or power may be provided, through the third component 110C, to the first component 110A from the second component 110B, and/or to the second component 110B from the first component 110A. Additionally, the fourth component 110D may connect (e.g., electrically connect) together the second component 110B and the fifth component 110E through the connections 190, such that communication or power may be provided, through the fourth component 110D, to the second component 110B from the fifth component 110E, and/or to the fifth component 110E from the second component 110B. Accordingly, communication or power may be provided between the first component 110A, the second component 110B, and/or the fifth component 110E, through the third component 110C and/or the fourth component 110D. For example, the third component 110C and/or the fourth component 110D may be or include a horizontal interposer that is configured to perform horizontal routing, as discussed above.

With reference to FIG. 10D, a semiconductor system 100D may include a plurality of modular components, wherein at least one of the modular components may be an active semiconductor component that is configured to perform additional functions that are substantially the same or similar to functions (e.g., transmitting and receiving functions) of an interposer. For example, the semiconductor system 100D may include the first component 110A, the second component 110B, and a sixth component 110F (e.g., a modular component) that may respectively be or include active semiconductor components. According to some embodiments, the first component 110A and the second component 110B may be vertically stacked on the sixth component 110F in such a manner that portions each of first component 110A and the second component B may overlap respective portions of the sixth component 110F, and may be connected (e.g., electrically connected) to respective overlapped portions of an upper surface of the sixth component 110F by at least one connection 190.

According to some embodiments, at least one from among the first component 110A, the second component 110B, and the sixth component 110F may be an active component that is additionally configured to perform functions that are substantially the same or similar to functions (e.g., transmitting and receiving functions) of an interposer. For example, the sixth component 110F may be configured to perform functions that are substantially the same or similar to functions of an interposer. For example, the sixth component 110F may connect (e.g., electrically connect) together the first component 110A and the second component 110B through the connections 190, such that communication or power may be provided, through the sixth component 110F, to the first component 110A from the second component 110B, and/or to the second component 110B from the first component 110A.

In some embodiments, the sixth component 110F may act as an interposer without modifying data that is moving across the sixth component 110F. In other embodiments, the sixth component 110F may modify, alter, or act upon the data moving across the sixth component 110F. As an example, the sixth component 110F may contain arithmetic logic, and may perform arithmetic on data moving across the sixth component 110F. For further example, data coming from first component 110A may be treated as input for a mathematical operation upon said data performed by the arithmetic logic of the sixth component 110F, and the sixth component 110F may transmit the result of said operation to the second component 110B.

As shown in FIGS. 10A-10D, a gap may be provided between vertically stacked components (e.g., the first component 110A and the second component 110B) due to the thickness of connections 190. However, embodiments of the present disclosure are not limited thereto. For example, depending on a bonding type of the connections 190, a gap may or may not be provided.

With reference to FIG. 11, a semiconductor system according to embodiments of the present disclosure may include various types of components (e.g., modular components) that are arranged and connected (e.g., electrically connected) vertically and/or horizontally with respect to one another. One or more (e.g., some or all) of the components (e.g., modular components) may have the configurations described above with references to FIGS. 1A-10D, and thus repeated descriptions thereof may be omitted.

For example, the semiconductor system 100E, may include a first component 120A, a second component 120B, a third component 120C, a fourth component 120D, a fifth component 120E, a sixth component 120F, a seventh component 120G, an eight component 120H, a ninth component 120I, a tenth component 120J, an eleventh component 120K, a twelfth component 120L, and a thirteenth component 120M, and one or more (e.g., some or all) of the first through thirteenth components 120A-120M may be a modular component that follows the design rules described in the present disclosure.

The first component 120A may be in a first layer (e.g., lowermost layer) of components of the semiconductor system 100E. The first component 120A may be directly connected (e.g., electrically connected) to the second component 120B, and may be configured to directly or indirectly connect (e.g., electrically connect) to at least one component below the first component 120A such as, for example, at least one component outside of the semiconductor system 100E. For example, the first component 120A may be or include an interposer such as, for example, a fan-out interposer. The fan-out interposer may be configured to expand input and/or output connections of other components (e.g., the second through thirteenth component 120B-120M), on the upper surface of the fan-out interposer, beyond an area of the other components in at least one horizontal directions (e.g., the X-direction and/or Y-direction), at the lower surface of the fan-out interposer. However, embodiments of the present disclosure are not limited thereto.

The second component 120B may be in a second layer (e.g., on the first layer) of the components of the semiconductor system 100E. The second component 120B may be directly connected (e.g., electrically connected) to the first component 120A, the third component 120C, and/or the fourth component 120D by at least one connection (e.g., the connections 190 described above). For example, the second component 120B may be or include an interposer such as, for example, a vertical and/or horizontal interposer. The vertical interposer may be configured to connect (e.g., electrically connect) other components. For example, in the configuration shown in FIG. 11, the second component 120B may directly or indirectly connect (e.g., electrically connect) together one or more upper components (e.g., the third through thirteenth component 120C-120M) and the first component 120A through the connections (e.g., the connections 190), such that communication or power may be provided between the upper components (e.g., the third through thirteenth component 120C-120M) and the first component 120A through the second component 120B. According to some embodiments, the second component 120B may be configured to perform cooling of at least one component adjacent to the second component 120B, which has been described in detail above with reference to FIGS. 9A-9B. However, embodiments of the present disclosure are not limited thereto.

The third component 120C and the fourth component 120D may be in a third layer (e.g., on the second layer) of the components of the semiconductor system 100E. However, embodiments of the present disclosure are not limited thereto.

The third component 120C may be directly connected (e.g., electrically connected) to the second component 120B, the fifth component 120E, and/or the sixth component 120F by at least one connection (e.g., the connections 190). For example, the third component 120C may be or include an active component such as, for example, an active semiconductor chip. For example, the active component (or active semiconductor chip) may refer to a component that is configured to generate, store, or process data. According to an embodiment, the active semiconductor chip may be or include a processor configured to perform processing. For example, the active semiconductor chip of the third component 120C may be or include a central processing unit (CPU). However, embodiments of the present disclosure are not limited thereto.

The fourth component 120D may be directly connected (e.g., electrically connected) to the second component 120B, the sixth component 120F, and/or the seventh component 120G by at least one connection (e.g., the connections 190). For example, the fourth component 120D may be or include an active component such as, for example, an active semiconductor chip. According to an embodiment, the active semiconductor chip may be or include memory. For example, the active semiconductor chip of the fourth component 120D may be or include Flash memory. However, embodiments of the present disclosure are not limited thereto.

The fifth component 120E, the sixth component 120F, and the seventh component 120G may be in a fourth layer (e.g., on the third layer) of the components of the semiconductor system 100E. However, embodiments of the present disclosure are not limited thereto.

The fifth component 120E may be directly connected (e.g., electrically connected) to the third component 120C and/or the eighth component 120H by at least one connection (e.g., the connections 190). For example, the fifth component 120E may be or include an interposer such as, for example, a vertical interposer. The vertical interposer may be configured to connect (e.g., electrically connect) other components, especially in the vertical direction. For example, in the configuration shown in FIG. 8, the fifth component 120E may directly or indirectly connect (e.g., electrically connect) together one or more upper components (e.g., the eight component 120H) and the third component 120C through the connections (e.g., the connections 190), such that communication or power may be provided between the upper components (e.g., the eight component 120H) and the third component 120C through the fifth component 120E. However, embodiments of the present disclosure are not limited thereto.

The sixth component 120F may be directly connected (e.g., electrically connected) to the third component 120C, the fourth component 120D, the eighth component 120H, and/or the ninth component 120I by at least one connection (e.g., the connections 190). For example, the sixth component 120F may be or include an interposer such as, for example, an all-points or all-directions interposer. For example, the all-points or all-directions interposer may be a type of interposer that is configured to perform horizontal and vertically routing. For example, in a same or similar manner as described above with respect to FIG. 5A, connection regions 10 (see FIGS. 1A-5B) of the sixth component 120F may be connected (e.g., electrically connected) to all other connection regions 10 of the sixth component 120F. For example, in the configuration shown in FIG. 11, the sixth component 120F may directly connect (e.g., electrically connect) together the third component 120C, the fourth component 120D, the eighth component 120H, and/or the ninth component 120I by the horizontal and/or vertical routing between the connection regions 10 of the sixth component 120F, such that communication or power may be provided between the third component 120C, the fourth component 120D, the eighth component 120H, and/or the ninth component 120I through the sixth component 120F, and so that all of said components may directly communicate with each other through the sixth component 120F (e.g., an all-points interposer). However, embodiments of the present disclosure are not limited thereto.

The seventh component 120G may be directly connected (e.g., electrically connected) to the fourth component 120D and/or the ninth component 120I by at least one connection (e.g., the connections 190). For example, similar to the fifth component 120E, the seventh component 120G may be or include an interposer such as, for example, a vertical interposer. The vertical interposer may be configured to directly or indirectly connect (e.g., electrically connect) other components. For example, in the configuration shown in FIG. 8, the seventh component 120G may directly or indirectly connect (e.g., electrically connect) together one or more upper components (e.g., the ninth through thirteenth component 120I-120M) and the fourth component 120D through the connections (e.g., the connections 190), such that communication or power may be provided between the upper components (e.g., the ninth through thirteenth component 120I-120M) and the fourth component 120D through the seventh component 120G. However, embodiments of the present disclosure are not limited thereto.

The eighth component 120H and the ninth component 120I may be in a fifth layer (e.g., on the fourth layer) of the components of the semiconductor system 100E. However, embodiments of the present disclosure are not limited thereto.

The eighth component 120H may be directly connected (e.g., electrically connected) to the fifth component 120E, the sixth component 120F, and/or the tenth component 120J by at least one connection (e.g., the connections 190). For example, the eighth component 120H may be or include an active component such as, for example, an active semiconductor chip. According to an embodiment, the active semiconductor chip may be or include a processor configured to perform processing. For example, the active semiconductor chip of the eighth component 120H may be or include a graphics processing unit (GPU). However, embodiments of the present disclosure are not limited thereto.

The ninth component 120I may be directly connected (e.g., electrically connected) to the sixth component 120F, the seventh component 120G, and/or the tenth component 120J by at least one connection (e.g., the connections 190). For example, the ninth component 120I may be or include an active component such as, for example, an active semiconductor chip. According to an embodiment, the active semiconductor chip may be or include memory. For example, the active semiconductor chip of the fourth component 120D may be or include dynamic random access memory (DRAM). However, embodiments of the present disclosure are not limited thereto.

The tenth component 120J may be in a sixth layer (e.g., on the fifth layer) of the components of the semiconductor system 100E. The tenth component 120J may be directly connected (e.g., electrically connected) to the eighth component 120H, the ninth component 120I, the eleventh component 120K, the twelfth component 120L, and/or the thirteenth component 120M by at least one connection (e.g., the connections 190). For example, the tenth component 120J may be or include an interposer such as, for example, a vertical interposer. As described above, the vertical interposer may be configured to connect (e.g., electrically connect) other components. For example, in the configuration shown in FIG. 8, the tenth component 120J may directly or indirectly connect (e.g., electrically connect) together one or more upper components (e.g., the eleventh through thirteenth component 120K-120M) and the eighth component 120H and/or the ninth component 120I through the connections (e.g., the connections 190), such that communication or power may be provided between the upper components (e.g., the eleventh through thirteenth component 120K-120M) and the eighth component 120H and/or the ninth component 120I through the tenth component 120J. According to some embodiments, the tenth component 120J may be configured to perform cooling of at least one component adjacent to tenth component 120J, which was described in detail above with reference to FIGS. 9A-9B. However, embodiments of the present disclosure are not limited thereto.

The eleventh component 120K, the twelfth component 120L, and the thirteenth component 120M may be in a seventh layer (e.g., on the sixth layer) of the components of the semiconductor system 100E. However, embodiments of the present disclosure are not limited thereto.

The eleventh component 120K and the twelfth component 120L may be directly connected (e.g., electrically connected) to the tenth component 120J by at least one connection (e.g., the connections 190). For example, the eleventh component 120K and the twelfth component 120L may respectively be or include an active component such as, for example, an active semiconductor chip. According to an embodiment, the active semiconductor chip may be or include memory. For example, the active semiconductor chip of the eleventh component 120K and the active semiconductor chip of the twelfth component 120L may be or include high bandwidth memory (HBM). However, embodiments of the present disclosure are not limited thereto.

The thirteenth component 120M may be directly connected (e.g., electrically connected) to the tenth component 120J and/or one or more components above the thirteenth component 120M by at least one connection (e.g., the connections 190). For example, the thirteenth component 120M may be or include an interposer such as, for example, a horizontal interposer. For example, as described above, the horizontal interposer may be a type of interposer that is configured to perform horizontal routing. For example, in a case where at least two components are provided on an upper surface (or a lower surface) of the thirteenth component 120M, the thirteenth component 120M may be configured directly or indirectly connect (e.g., electrically connect) together the at least two components through the connections (e.g., the connections 190), such that communication or power may be provided, through the thirteenth component 120M, between the at least two components. For example, the thirteenth component 120M may provide communications between the eighth component 120H and the ninth component 120I by, for example, communication from the eighth component 120H travelling upwards through the tenth component 120J, then across the thirteenth component 120M (in a rightwards direction relative to FIG. 11), travelling downwards through the tenth component 120J, and then into the ninth component 120I. According to some embodiments, the thirteenth component 120M may have a same or similar configuration to the configuration of the third component 110C and/or the fourth component 110D described above with reference to FIG. 10C. However, embodiments of the present disclosure are not limited thereto.

According to embodiments of the present disclosure, modular components (e.g., components 1, 1A, 1B, 1C, 110A-110F, 120A-120L, 210, 220, and 310; see FIGS. 1-11) may be provided, wherein dimensions and/or relationships of the modular components and their connection regions conform with design rules (described above) that enable the modular components and their interconnectors to be assembled together in various configurations, thereby maximizing flexibility and cross-compatibility in manufacturing different semiconductor systems. Accordingly, a user may freely customize an arrangement of the components within the semiconductor system, and capabilities of the semiconductor system.

For example, with reference to FIG. 11, one or more (e.g., some or all) of the components (e.g., the first through thirteenth component 120A-120M) of the semiconductor system 100E may have dimensions that are substantially equal to, or an integer multiple of dimensions of a fundamental unit, as described above with reference to FIGS. 1A-3B. Alternatively or additional, one or more (e.g., some or all) of the components (e.g., the first through thirteenth component 120A-120M) of the semiconductor system 100E may include connection regions that include a uniform arrangement of the interconnectors, and distances between neighboring ones of the connection regions may substantially be the same as one another, or integer multiples of one another, as described above with reference to FIGS. 1A-3B. Alternatively or additionally, connection regions of one or more (e.g., some or all) of the components (e.g., the first through thirteenth component 120A-120M) of the semiconductor system 100E may omit at least one connection region as described above with reference to FIG. 3A.

As a non-limiting example, size relationships of some of the components (e.g., the first through thirteenth component 120A-120M) of the semiconductor system 100E include, but are not limited to:

(a) The eleventh component 120K having a width in the first horizontal direction (e.g., the X-direction) that is substantially an integer multiple (e.g., 2 times) of the fundamental unit width W1 (see FIG. 1B), a width in the second horizontal direction (e.g., the Y-direction) that is substantially an integer multiple (e.g., 2 times) of the fundamental unit width W2 (see FIG. 1B), and a thickness in the vertical direction (e.g., the Z-direction) that is substantially equal to the fundamental unit thickness T (see FIG. 1A).

(b) The thirteenth component 120M having a width in the first horizontal direction (e.g., the X-direction) that is substantially an integer multiple (e.g., 4 times) of the fundamental unit width W1 (see FIG. 1B), a width in the second horizontal direction (e.g., the Y-direction) that is substantially an integer multiple (e.g., 4 times) of the fundamental unit width W2 (see FIG. 1B), and a thickness in the vertical direction (e.g., the Z-direction) that is substantially equal to the fundamental unit thickness T (see FIG. 1A).

(c) The tenth component 120J having a width in the first horizontal direction (e.g., the X-direction) that is substantially an integer multiple (e.g., 6 times) of the fundamental unit width W1 (see FIG. 1B), a width in the second horizontal direction (e.g., the Y-direction) that is substantially an integer multiple (e.g., 4 times) of the fundamental unit width W2 (see FIG. 1B), and a thickness in the vertical direction (e.g., the Z-direction) that is an integer multiple (e.g., 2 times) of the fundamental unit thickness T (see FIG. 1A).

The widths and thicknesses of modular components described above are non-limiting examples, and the widths and thicknesses of modular components may be variously provided, assuming they follow design rules as described in embodiments of the present disclosure. According to some embodiments, one or more (e.g., some or all) of the widths of the components may be substantially equal to, or an integer multiple of, the fundamental unit width W1 (see FIG. 1B) and/or the fundamental unit width W2 (see FIG. 1B). According to some embodiments, one or more (e.g., some or all) of the thicknesses of the components may be substantially equal to, or an integer multiple of, the fundamental unit thickness T (see FIG. 1A).

According to embodiments described above, the components and their connection regions may be assembled together in various configurations, thereby maximizing flexibility and cross-compatibility in manufacturing different semiconductor systems. For example, modular components according to embodiments of the present disclosure may be easily interchanged, removed, and/or added in semiconductor systems.

As an example of how modular semiconductor systems according to embodiments of the present disclosure may be varied, one or more of the modular components (e.g., the first through thirteenth component 120A-120M) or layers shown in FIG. 11 may be omitted. For example, the thirteenth component 120M may be omitted. Alternatively or additionally, one or more components may be added in the first through seventh layers of the semiconductor system 100E described above, or in an additional layer(s) of the semiconductor system 100E.

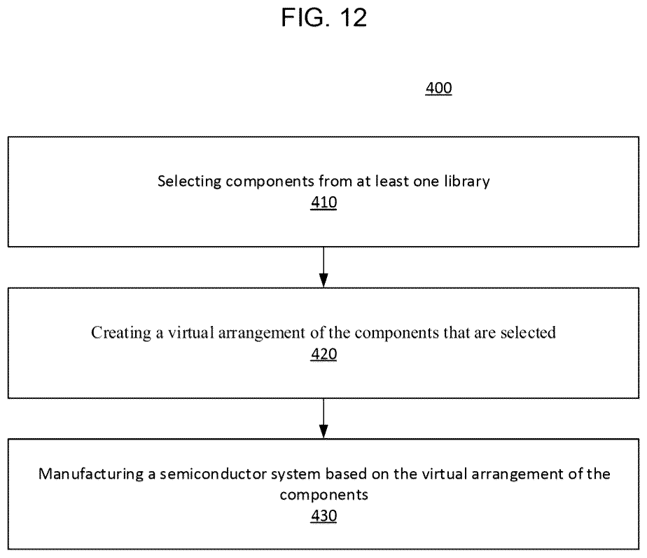

According to some embodiments, with reference to FIG. 12, a method 400 of manufacturing a semiconductor system may be provided. For example, the method may include selecting components pre-defined within at least one library (also referred to as “pre-defined components”) from the at least one library (operation 410), creating a virtual arrangement of the components that are selected (operation 420), and manufacturing the semiconductor system based on the virtual arrangement of the components that are selected (operation 430).

In the operation 410, a user may select components from at least one library (operation 410). For example, a user may use an input device (e.g., a mouse, a keyboard, a microphone, a touchscreen, etc.) of a computer system to select one or more components from the at least one library. According to some embodiments, at least one list of the libraries and/or components therein may be displayed on a display device of the computer system, and the components may be selected on the display device by the user using the input device.

According to some embodiments, the components may be modular components (e.g., components 1, 1A, 1B, 1C, 110A-110F, 120A-120L, 210, 220, and 310) that have configurations described above with reference to FIGS. 1A-11. However, embodiments of the present disclosure are not limited thereto.

According to some embodiments, the components (e.g., modular components) may have widths that are substantially equal to, or an integer multiple of, the fundamental unit width W1 (see FIG. 1B) and/or the fundamental unit width W2 (see FIG. 1B), respectively, and/or a thickness substantially equal to, or an integer multiple of, the fundamental unit thickness T (see FIG. 1A). Additionally, the components may include connection regions that include a uniform arrangement of interconnectors, and distances between neighboring ones of the connection regions may substantially be the same as one another, or integer multiples of one another, as described above with reference to FIGS. 1A-3B. Alternatively or additionally, connection regions of one or more (e.g., some or all) of the components may omit at least one connection region as described above with reference to FIG. 3A. However, embodiments of the present disclosure are not limited thereto.

The components (e.g., modular components) may be of various types including, for example, processor devices, memory devices, accelerator devices, sensor devices, interposer devices, etc. According to some embodiments, the components may include a combination of at least two from among the processor devices, memory devices, accelerator devices, sensor devices, interposer devices, etc.

The processor devices may be configured to perform processing, and may include, for example, devices of varying processing power. According to some embodiments, the processor devices may include, for example, CPUs, GPUs, etc. However, embodiments of the present disclosure are not limited thereto. According to some embodiments, the components that are or include processing devices may be stored in a processing device library, and may be selected during the operation 410.

The memory devices may be configured to store data temporarily and/or permanently, and may include devices of various types, data writing and/or reading speeds, capacities, additional features, etc. The memory devices may include, for example, HBM, A-HBM, static random access memory (SRAM), non-volatile memory (NVM) (e.g., flash memory), etc. However, embodiments of the present disclosure are not limited thereto. According to some embodiments, the components that are or include memory devices may be stored in at least one memory device library, and may be selected during the operation 410. For example, the at least one memory device library may be include a first memory device library for memory devices configured to store data temporarily, and/or a second memory device library for memory devices (also referred to as storage devices) configured to store data substantially permanently.

The accelerator devices may be specialized devices configured to enhance performance and/or energy efficiency of computing tasks, and may include, for example, application-specific integrated circuits (ASICS), field-programmable gate arrays (FPGAs), neural processing units (NPUs), etc. However, embodiments of the present disclosure are not limited thereto. According to some embodiments, the components that are or include accelerator devices may be stored in an accelerator device library, and may be selected during the operation 410.

The sensor devices may be configured to sense at least one characteristic of a semiconductor system in which the sensor device is provided, and may include, for example, accelerometers, photo sensors, etc. However, embodiments of the present disclosure are not limited thereto. According to some embodiments, the components that are or include sensor devices may be stored in a sensor device library, and may be selected during the operation 410.

The interposer devices may be interposers that are configured to be provided between at least two other components in a semiconductor system, and that provide an electrical signal(s) and/or power between the at least two other components. The interposer devices may include, for example, thermal interposers, power interposers, instrumentation interposers, etc. The interposer devices may also be or include active or passive interposers. However, embodiments of the present disclosure are not limited thereto. The active interposers may include active circuitry (e.g., transistors, logic gates, memory, etc.), while the passive interposers may not include the active circuitry. According to some embodiments, the components that are or include the interposer devices may be stored in an interposer device library, and may be selected during the operation 410.

In the operation 420, a user may create a virtual arrangement of the components that are selected by using the input device of the computer system. Example arrangements have been described above with reference to FIGS. 10A-11. However, embodiments of the present disclosure are certainly not limited thereto. For example, in view of dimensions and/or relationships of the components and their connection regions conforming with design rules as described in the present disclosure, the components may be virtually arranged (and connected) in various positions in the horizontal directions (e.g., the X-direction and/or the Y-direction) and/or vertical direction (e.g., Z-direction) relative to one another, and have various rotational orientations relative to one another. According to some embodiments, the virtual arrangement may be displayed on the display device of the computer system, and may be selected (or modified) by the user using the input device. For example, in the operation 410, the user may use the input device to select positions of the components in the horizontal directions (e.g., the X-direction and/or the Y-direction) and/or vertical direction (e.g., Z-direction), and rotational orientations of the components, in the virtual arrangement.

According to some embodiments, the selecting sub-operations of the operation 410 and the selecting sub-operations of the operation 420 may be respectively performed a plurality of times. According to some embodiments, the operation 410 and the operation 420 may be performed sequentially or simultaneously. For example, at least one selecting sub-operation of the operation 410 may be interleaved between selecting sub-operations of the operation 420. For example, a first component may be selected and virtually placed. A second component may then be selected and virtually placed connecting to the first component, and so on, until all desired components have been selected and placed.

The operation 430 may include manufacturing the semiconductor system to have an arrangement corresponding to (e.g., the same as or substantially the same as) the virtual arrangement of the components. For example, the computer system may control semiconductor manufacturing equipment to manufacture the components included in the virtual arrangement and/or assemble the components to have the arrangement corresponding to the virtual arrangement. For example, the semiconductor manufacturing equipment may include at least one from among a lithography machine, a deposition tool (e.g., an atomic layer deposition (ALD) system, a chemical vapor deposition system (CVD), etc.), dry etchers, sputtering systems, dicers, wafer cleaners, robots, etc. According to some embodiments, the components may be manufactured separately from the method 400. For example, the components may be pre-made. In such case, the operation 430 may include manufacturing the semiconductor system by assembling the components to have the arrangement corresponding to the virtual arrangement, without manufacturing the components.

According to some embodiments, prior to the operation 410, the method 400 may further include assembling the at least one library to include the modular components. By the at least one library including the modular components, the modular components may be considered to be pre-defined components within the at least one library.

According to some embodiments, the computer system may include, for example, at least one processor, a memory, the display, the input device, etc. The memory may store computer instructions that are configured to, when executed by the at least one processor, cause the computer system to perform its functions. The memory may also store the libraries described above with reference to operation 410.

The present disclosure is presented to enable one of ordinary skill in the art to make and use the present disclosure and to incorporate it in the context of particular applications. While the foregoing is directed to specific examples, other and further examples may be devised without departing from the scope of the present disclosure.

Various modifications, as well as a variety of uses in different applications will be readily apparent to those skilled in the art, and the general principles defined herein may be applied to a wide range of embodiments. Thus, the present disclosure is not intended to be limited to the example embodiments presented herein, and is to be accorded the widest scope consistent with the principles and novel features disclosed herein.

In the description provided, numerous specific details are set forth in order to provide a more thorough understanding of the present disclosure. However, it will be apparent to one skilled in the art that the present disclosure may be practiced without necessarily being limited to these specific details. In other instances, well-known structures and devices are shown in block diagram form, rather than in detail, in order to avoid obscuring the present disclosure.

All the features disclosed in this specification, (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Various features are described in the present disclosure with reference to the drawings. It should be noted that the drawings are only intended to facilitate the description of the features. They are not intended as an exhaustive description of the present disclosure or as a limitation on the scope of the present disclosure. In addition, an illustrated example need not have all the aspects or advantages shown. An aspect or an advantage described in conjunction with a particular example is not necessarily limited to that example and can be practiced in any other examples even if not so illustrated, or if not so explicitly described.

Furthermore, any element in a claim that does not explicitly state “means for” performing a specified function, or “step for” performing a specific function, is not to be interpreted as a “means” or “step” clause as specified in 35 U.S.C. § 112(f). In particular, the use of “step of” or “act of” in the claims herein is not intended to invoke the provisions of 35 U.S.C. § 112(f).

The labels “left,” “right,” “front,” “back,” “top,” “bottom,” “forward,” “reverse,” “clockwise” and “counter clockwise,” if used, have been used for convenience purposes only and are not intended to imply any particular fixed direction. Instead, they are used to reflect relative locations and/or directions between various portions of an object.

While embodiments have been described with respect to circuit functions, the embodiments of the present disclosure are not limited. Possible implementations, may be embodied in a single integrated circuit, a multi-chip module, a single card, system-on-a-chip, or a multi-card circuit pack. As would be apparent to one skilled in the art, the various embodiments might also be implemented as part of a larger system. Such embodiments might be employed in conjunction with, for example, a digital signal processor, microcontroller, field-programmable gate array, application-specific integrated circuit, or general-purpose computer.

For the sake of brevity, conventional elements to semiconductor devices may or may not be described in detail herein. However, even if a certain element is described or illustrated in a semiconductor device in the present disclosure, the element may not be included in a claimed semiconductor device unless the element is recited as being included in the claimed semiconductor device. Also, when a particular method for deposition or etching used in manufacturing a semiconductor device is or is not mentioned herein, it will be understood that a conventional method for such deposition or etching may be applied in corresponding steps of manufacturing the semiconductor device.

While non-limiting example embodiments have been described above in connection with the drawings, it will be apparent to those skilled in the art that modifications and variations could be made without departing from the scope of the present disclosure.

What is claimed is:

1. A semiconductor system comprising:
a plurality of components comprising:
a first component comprising first connection regions at a first surface of the first component; and
a second component comprising second connection regions at a first surface of the second component,
wherein at least one of the first connection regions is connected to at least one of the second connection regions,
wherein a first width of the first component in a first horizontal direction is substantially a first integer multiple of a first fundamental unit width in the first horizontal direction, and
wherein a first width of the second component in the first horizontal direction is substantially a second integer multiple of the first fundamental unit width, the second integer multiple being different from the first integer multiple.

2. The semiconductor system of claim 1, wherein a second width of the first component in a second horizontal direction, crossing the first horizontal direction, is substantially the same as a second fundamental unit width in the second horizontal direction or a third integer multiple of the second fundamental unit width, and
wherein a second width of the second component in the second horizontal direction is substantially the same as the second fundamental unit width in the second horizontal direction or a fourth integer multiple of the second fundamental unit width.

3. The semiconductor system of claim 1, wherein a thickness of the first component in a vertical direction is substantially the same as a fundamental unit thickness in the vertical direction or a third integer multiple of the fundamental unit thickness, and
wherein a thickness of the second component in the vertical direction is substantially the same as the fundamental unit thickness in the vertical direction or a fourth integer multiple of the fundamental unit thickness.

4. The semiconductor system of claim 1, wherein the first connection regions are arranged in a first array and have first sizes and first shapes, and the second connection regions are arranged in a second array and have the first sizes and the first shapes.

5. The semiconductor system of claim 1, wherein a distance between at least two neighboring ones of the first connection regions in the first horizontal direction is the same as a distance between at least two neighboring ones of the second connection regions in the first horizontal direction.

6. The semiconductor system of claim 1, wherein a distance between at least two neighboring ones of the first connection regions in the first horizontal direction is an integer multiple of a distance between at least two neighboring ones of the second connection regions in the first horizontal direction.

7. The semiconductor system of claim 1, wherein a distance between neighboring ones of the first connection regions in the first horizontal direction and a distance between neighboring ones of the second connection regions in the first horizontal direction are substantially equal to the first integer multiple and the second integer multiple.

8. The semiconductor system of claim 1, wherein a size and a shape of the first connection regions are the same as a size and a shape of the second connection regions.

9. The semiconductor system of claim 1, wherein at least one of the first connection regions comprises a plurality of first interconnectors that are arranged in a first array, and
wherein at least one of the second connection regions comprises a plurality of second interconnectors that are arranged in a second array.

10. The semiconductor system of claim 1, wherein one from among the first component and the second component comprises a semiconductor chip, and the other from among the first component and the second component comprises an interposer.

11. The semiconductor system of claim 1, wherein one from among the first component and the second component comprises a first semiconductor chip configured to perform processing, and the other from among the first component and the second component comprises a second semiconductor chip configured as memory.

12. The semiconductor system of claim 1, wherein the first component further comprises third connection regions at a second surface of the first component, the third connection regions respectively overlapping with the first connection regions; and
wherein the second component further comprises fourth connection regions at a second surface of the second component, the fourth connection regions respectively overlapping with the second connection regions.

13. The semiconductor system of claim 1, wherein a second width of the first component in a second horizontal direction, crossing the first horizontal direction, is substantially the same as a second fundamental unit width in the second horizontal direction or a third integer multiple of the second fundamental unit width,
wherein a second width of the second component in the second horizontal direction is substantially the same as the second fundamental unit width in the second horizontal direction or a fourth integer multiple of the second fundamental unit width, and
wherein the first connection regions have a same shape and a same size, and the second connection regions have a same shape and a same size.

14. The semiconductor system of claim 1, wherein a distance between neighboring ones of the first connection regions in the first horizontal direction is substantially equal to a distance between neighboring ones of the second connection regions in the first horizontal direction, and
wherein a distance between neighboring ones of the first connection regions in a second horizontal direction, crossing the first horizontal direction, is substantially equal to a distance between neighboring ones of the second connection regions in the second horizontal direction.

15. The semiconductor system of claim 1, wherein a distance between neighboring ones of the first connection regions in the first horizontal direction and a distance between neighboring ones of the second connection regions in the first horizontal direction are substantially equal to the first fundamental unit width in the first horizontal direction or an integer multiple thereof.

16. The semiconductor system of claim 1, wherein the first connection regions are symmetrically arranged, and
wherein the second connection regions are symmetrically arranged.

17. The semiconductor system of claim 16, wherein a first connection region among the first connection regions is connected through the first component to another first connection region among the first connection regions,
wherein a position of the first connection region is symmetrical with respect to a position of the other first connection region across a line of symmetry passing through a center of the first component in a plan view of the first component.

18. A method of manufacturing a semiconductor system, the method comprising:
selecting, by a computer system, components that are pre-defined in at least one library;
creating, by the computer system, an arrangement of the components that are selected; and
manufacturing the semiconductor system to include the components in the arrangement,
wherein the components include:
a first component including first connection regions at a first surface of the first component; and
a second component including second connection regions at a first surface of the second component,
wherein, in the arrangement, at least one of the first connection regions is connected to at least one of the second connection regions,
wherein a first width of the first component in a first horizontal direction is substantially equal to a first integer multiple of a first fundamental unit width in the first horizontal direction, and
wherein a first width of the second component in the first horizontal direction is substantially equal to a second integer multiple of the first fundamental unit width, the second integer multiple being different from the first integer multiple.

19. A device configured to electrical connect semiconductor components, the device comprising:
a body;
first connection regions arranged in a first pattern at a first surface of the body, the first connection regions respectively comprising a plurality of first interconnectors arranged in a second pattern; and
second connection regions arranged in the first pattern at a second surface of the body, opposite of the first surface, the second connection regions respectively comprising a plurality of second interconnectors arranged in the second pattern,
wherein the plurality of first interconnectors of one of the first connection regions are connected to the plurality of first interconnectors of at least one other of the first connection regions or the plurality of second interconnectors of at least one of the second connection regions.

20. The device of claim 19, wherein, in a first connection region from among the first connection regions, at least two of the plurality of first interconnectors are routed in respective, different directions to respective different ones of the first connection regions or the second connection regions.
